(19) United States
(12) Patent Application Publication
(10) Pub. No.: US 2025/0130299 A1
(43) Pub. Date: Apr. 24, 2025

(54) SYSTEMS AND METHODS FOR QUANTIFYING SODIUM CONCENTRATION

(71) Applicant: New York University, New York, NY (US)

(72) Inventors: Yongxian Qian, Forest Hills, NY (US); Fernando E. Boada, Purchase, NY (US)

(73) Assignee: New York University, New York, NY (US)

(21) Appl. No.: 18/920,506

(22) Filed: Oct. 18, 2024

Related U.S. Application Data
(60) Provisional application No. 63/591,751, filed on Oct. 19, 2023.

(51) Int. Cl. G01R 33/56; G01R 33/50

(52) U.S. Cl. CPC G01R 33/56; G01R 33/50

(57) ABSTRACT

A method of quantifying sodium concentration can include extracting one or more bi-T₂ sodium signals from one or more echo time acquisitions. The method can include separating, via a matrix equation including at least one of T₂ decays or T₂* decays of mono-T₂ sodium and bi-T₂ sodium, an intensity of the one or more bi-T₂ sodium signals from an intensity of one or more mono-T₂ sodium signals. The method can include quantifying bi-T₂ sodium concentration, mono-T₂ sodium concentration, and total sodium concentration based on the one or more echo time acquisitions. The one or more echo time acquisitions can be performed with single-quantum sodium excitations.

### CROSS-REFERENCE TO RELATED APPLICATIONS

This application claims the benefit of and priority to U.S. Provisional Patent Application No. 63/591,751, filed Oct. 19, 2023, the contents of which is incorporated by reference herein in its entirety for all purposes.

### STATEMENT OF GOVERNMENT INTEREST

This invention was made with Government support under NS113517 and CA111996 awarded by the National Institutes of Health (NIH). The government has certain rights in the invention.

### TECHNICAL FIELD

The present disclosure relates generally to a process of multiple echo time acquisitions for quantitative bi-T₂ sodium (²³Na) magnetic resonance imaging (MRI).

### BACKGROUND

In human brains, sodium ions (Na⁺), when exposed to an electrical field gradient of negatively charged macromolecules and proteins, can experience a nuclear quadrupolar interaction that results in biexponential decay in transverse (T₂) relaxation of nuclear spins when the ions are not in fast motion, a situation in which correlation time between sodium ions and electrical field gradient is much shorter than the inverse of Larmor frequency, τ_{c}<<1/ω₀. Sodium ions in fast motion can cancel out the effect of quadrupolar interactions, resulting in mono-exponential T₂ decay.

### SUMMARY

The systems and methods of the present disclosure can improve the accuracy of sodium quantification by completely eliminating residual mono-T₂ sodium signal in the bi-T₂ sodium image. This advancement can make sodium MRI suitable for quantification of bi-T₂ sodium concentration in a clinical setting at 3 Tesla or higher.

In the present disclosure, those showing mono-exponential T₂ decay is referred to as “mono-T₂” sodium and those showing bi-exponential T₂ decay as “bi-T₂” sodium. Both mono-T₂ and bi-T₂ sodium can appear in intracellular and extracellular spaces.

The bi-T₂ sodium concentration can serve as an endogenous molecular imaging biomarker for noninvasive assessment of pathological alterations of cells in humans at an early stage or adverse progressions of diseases at a late stage. Normal cells in the brain, for instance, can maintain their sodium concentration at a low level of ˜15 mM in intracellular space against a high level of ˜145 mM in extracellular space. Abnormal cells, such as cancer cells, can allow intracellular sodium concentration to rise by as much as 200%.

One aspect of the present disclosure relates to a method of quantifying sodium concentration. The method can include extracting bi-T₂ sodium signal from two or more echo time acquisitions. The method can include separating, via a matrix equation including at least one of T₂ (or T₂*) decays of mono-T₂ sodium and bi-T₂ sodium, an intensity of the bi-T₂ sodium signal from an intensity of mono-T₂ sodium signal. The two or more echo time acquisitions can be performed with single-quantum sodium excitations. The two or more echo time acquisitions can simultaneously quantify bi-T₂ sodium concentration, mono-T₂ sodium concentration, and total sodium concentration (e.g., the sum of mono-T₂ and bi-T₂ sodium concentrations).

Another aspect of the present disclosure relates to a non-transitory computer-readable medium having computer-readable instructions stored thereon that, when executed by at least one controller, cause the at least one controller to extract one or more bi-T₂ sodium signals from one or more echo time acquisitions. The at least one controller can separate, via a matrix equation including at least one of T₂ decays or T₂* decays of mono-T₂ sodium and bi-T₂ sodium, an intensity of the one or more bi-T₂ sodium signals from an intensity of one or more mono-T₂ sodium signals. The at least one controller can quantify bi-T₂ sodium concentration, mono-T₂ sodium concentration, and total sodium concentration based on the one or more echo time acquisitions. The one or more echo time acquisitions can be performed with single-quantum sodium excitations.

### BRIEF DESCRIPTION OF THE FIGURES

The disclosure will become more fully understood from the following detailed description, taken in conjunction with the accompanying figures, wherein like reference numerals refer to like elements, in which:

FIG. 1 illustrates a flowchart of the multi-TE single-quantum (MSQ) sodium MRI technique, according to an example implementation.

FIGS. 2A-2F illustrate FID signals and T₂* spectra from whole brain of a healthy human subject (52 years old, male) with and without the correction for FID distortion, according to an example implementation.

FIGS. 3A-3F illustrate simulated impact of estimated T₂* values on the separation of mono-T₂ and bi-T₂ sodium signals (Mₘₒ, M_{bi}), according to an example implementation.

FIGS. 4A-4E illustrate TE scheme optimization via the singular value decomposition (SVD) singular values, according to an example implementation.

FIGS. 5A-5F illustrate simulated separation of the mono-T₂ and bi-T₂ sodium signals, according to an example implementation.

FIGS. 6A-6I illustrate the results of a phantom study, according to an example implementation.

FIGS. 7A-7C illustrate the results of a human study, according to an example implementation.

FIGS. 8A-8M illustrate the results of human study #1 (26-year-old female, healthy), according to an example implementation.

FIGS. 9A-9M illustrate the results of human study #2 (59-year-old male, bipolar disorder patient), according to an example implementation.

FIGS. 10A-10C illustrate the upper-limit volume fraction of extracellular and intracellular spaces by assigning all the mono-T₂ sodium into extracellular space at Cₑₓ=145 mM and all the bi-T₂ sodium into intracellular space at Cᵢₙ=15 mM, according to an example implementation.

FIGS. 11A-11D illustrate the calculation stability of T₂* spectra, according to an example implementation.

FIGS. 12A-12D illustrate the calculation stability of T₂* spectra, according to an example implementation.

FIGS. 13A-13C illustrate whole-brain histograms of ΔB₀ mapping at TE₁/TE₂=0.5/5 ms under a manual shimming procedure, according to an example implementation.

FIGS. 14A-14B illustrate representative whole-brain histograms of single-T₂* mapping at TE₁/TE₂=0.5/5 ms, according to an example implementation.

FIG. 15 illustrates a method of quantifying sodium concentration, according to an example implementation.

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION

Before turning to the figures, which illustrate certain exemplary embodiments in detail, it should be understood that the present disclosure is not limited to the details or methodology set forth in the description or illustrated in the figures. It should also be understood that the terminology used herein is for the purpose of description only and should not be regarded as limiting.

Sodium ions in bi-exponential T₂ decay were historically, but incorrectly, considered as invisible “bound” (chemically) sodium because their short-T₂ components were not detectable by then-NMR (nuclear magnetic resonance) techniques. The terminology however remains in use in today's sodium MRI, although concerns have been raised recently by some researchers, with no better substitutes yet. For clarity, this disclosure refers “bi-T₂” sodium to those showing bi-exponential T₂ decay and “mono-T₂” sodium to those showing mono-exponential T₂ decay. The mono-T₂ and bi-T₂ sodium ions can appear in both intracellular and extracellular spaces, depending on their relative correlation time with electric field gradient.

Sodium (²³Na) MRI can acquire signals from both mono-T₂ and bi-T₂ sodium ions, and can quantify total sodium concentration (TSC) at voxels of an image. TSC can be a unique measure for non-invasive assessment of disruption in ionic homeostasis of cells in, or recovery from, pathological conditions such as stroke, tumor, multiple scleroses, epilepsy, bipolar disorder, and mild traumatic brain injury. However, TSC can be dominated by mono-T₂ sodium from cerebrospinal fluid (CSF) which has a high sodium concentration (˜145 mM) and overshadows alteration in intracellular sodium which has a much lower concentration (˜15 mM). Separation of mono- and bi-T₂ sodium signals can remove CSF impact and highlight intracellular alterations, especially at early stage of a disease happening at cellular level or in early (cellular) response to a treatment.

Complete separation of the mono-T₂ and bi-T₂ sodium signals can be crucial for sodium MRI to be used in clinical studies and in development of quantitative image biomarkers for non-invasive assessment of the ionic homeostasis of cells during early-stage pathological alterations and late-stage progressions of diseases such as brain tumors, multiple sclerosis, epilepsy, bipolar disorder, mild traumatic brain injury, and other neurological disorders or degenerations.

The difference in T₂ relaxation in sodium (²³Na) MRI can be a way to separate mono-T₂ and bi-T₂ sodium ions (e.g., the two populations of sodium) in the brain. Triple-quantum filtering (TQF) techniques can be a standard for human studies, in which MR signals are generated solely from triple-quantum (TQ) transitions. TQF techniques, however, can require multiple radiofrequency (RF) pulses for excitation and multi-step phase cycling to eliminate single-quantum (SQ) signals, leading to high specific absorption rate (SAR) and long scan time (e.g., 20-40 min). More problematic is that TQF can have a much lower signal-to-noise ratio (SNR) approximately 10 times lower than SQ. These difficulties can hamper TQF for widespread use on humans. These difficulties can hamper TQF's widespread use on humans.

Inversion recovery (IR), adopted from proton (¹H) MRI, can exploit a difference in T₁ relaxation between the mono-T₂ and bi-T₂ sodium ions, and can suppress signals from the mono-T₂ sodium of longer T₁ time. The IR approach can require an extra RF pulse for the suppression and can produce high SAR (e.g., worsens SAR) not favorable to human studies. It can also suffer from incomplete suppression of the mono-T₂ sodium signals which are much higher (e.g., about 10 times higher) than the bi-T₂ sodium signals, due to spatial inhomogeneity of B₁⁺ field although adiabatic pulses are usually used, and can complicate quantification of the bi-T₂ sodium owing to unknown residual mono-T₂ sodium signals. The power of the IR pulse can be a problem for SAR limitation. To overcome these drawbacks, another alternative approach, called short-T₂ imaging, was proposed in which SQ images were acquired at multiple echo times (TEs) and then subtracted from each other to produce an image of the short-T₂ component of bi-T₂ sodium. In such a way, SAR was reduced to, and SNR was increased to, the level of SQ images, favorable to human studies in clinic. Unfortunately, the subtraction may not completely eliminate mono-T₂ sodium signal (˜20% in residual), degrading accuracy of bi-T₂ sodium quantification.

A bi-T₂ sodium weighted image can be obtained by subtracting, with a T₂*-related weighting, a single-quantum (SQ) sodium image acquired at a long echo time of 11 ms from a spin-density weighted sodium image acquired at a very short echo time of 0.3 ms. The k-space data for both sodium images can be acquired in single run of a gradient-selective three-RF-pulse sequence without phase cycling. However, the approach did not improve SAR limitation as it still needs three RF pulses for excitation.

Short-T₂ imaging is an approach in which SQ images can be acquired at two echo times (TEs) and then subtracted from each other to produce an image of the short-T₂ component of the bi-T₂ sodium. In such a way, SAR can be reduced to, and SNR can be increased to, the level of SQ images which are favorable to human studies in a clinical setting. However, the subtraction may not completely eliminate the mono-T₂ sodium signal (˜20% in residual) and degrade accuracy of the bi-T₂ sodium quantification. Two SQ sodium images can be acquired at a short echo time (e.g., TE=0.5 ms) and a long echo time (e.g., TE=5 ms). The long-TE image can then be subtracted from the short-TE image to produce a short-T₂ image which is dominated by bi-T₂ sodium signal. This approach can have a high SNR for bi-T₂ sodium and no issue with SAR limitation during data acquisitions, but it can have a moderate accuracy in bi-T₂ sodium quantification due to a residual signal (e.g., 20%) from mono-T₂ sodium.

Described herein are system, methods, and apparatuses for quantifying sodium concentration. The system, methods, and apparatuses can be related to quantifying bi-T₂ sodium concentration using multiple echo time (TE) acquisitions in sodium magnetic resonance imaging (MRI). The bi-T₂ sodium signal can be extracted from multiple TE acquisitions that track T₂ (or T₂*) decays of mono-exponential and bi-exponential components and differentiate bi-T₂ sodium from mono-T₂ sodium. The bi-T₂ sodium signal intensity at voxel r, α(r), can be completely separated from mono-T₂ sodium signal intensity, β(r), through a matrix equation that eliminates contamination between the two sodium signals. The matrix equation can be uniquely characterized by the T₂ (or T₂*) decays of both mono-T₂ and bi-T₂ sodium, and the T₂ (or T₂*) values can be estimated from a mono-T₂ induction decay (FID) signal acquired from whole imaging volume. The multiple TE acquisitions at TE₁, TE₂, . . . , TEₙ can be performed with SQ sodium excitations that make the SNR of bi-T₂ sodium signal 6-times higher compared with TQF excitations. The multiple TE acquisitions with SQ sodium excitations may have no concern on the SAR restriction for subject safety, because single 90°-RF pulse may be needed for SQ excitation. The multiple TE acquisitions can simultaneously quantify the concentrations, C, of bi-T₂ sodium, mono-T₂ sodium, and total sodium through an integrated calibration. The systems and methods of the present disclosure can be applied to clinical MRI scanners at 3T or higher for patients with brain tumors or other neurological disorders such as stroke, bipolar disorder, epilepsy, multiple sclerosis (MS), mild traumatic brain injury (mTBI), and Alzheimer's disease or other forms of dementia.

In the human brain, intracellular sodium ions (Na⁺) can be in slow and restricted motion due to their binding to negatively-charged macromolecules while their extracellular counterparts are in fast and unrestricted motion. This difference in motion properties can lead to changes in bi-exponential transverse decay of mono-T₂ and bi-T₂ sodium ions. The systems and methods of the present disclosure can separate mono-T₂ and bi-T₂ sodium using single-quantum sodium images, without the SNR and SAR limitations as encountered in the triple-quantum filtering approach.

A change in intracellular sodium concentration can be detected by distinguishing between bi-T₂ and mono-T₂ sodium. Inside a cell, negatively-charged macromolecules or proteins (A⁻) can provide extensive binding sites for positively-charged sodium ions (Na⁺), which can restrict and slow down motion of sodium ions. This can lead to sodium nuclear spin-spin (or T₂) relaxation of bi-exponential decay, with 60% intensity for a short-T₂ component and 40% for a long-T₂ component. Outside of the cells, sodium ions can be in mono-T₂ and fast motion and their T₂ relaxations can decay mono-exponentially. Therefore, bi-T₂ sodium and its special feature of bi-exponential T₂ decay can be used to detect a change in intracellular sodium.

Bi-T₂ sodium concentration can be non-invasively quantified. This can be challenging for magnetic resonance imaging (MRI) because of various technical difficulties. First, MRI signals from intracellular sodium can have a very low signal-to-noise ratio (SNR). For example, the SNR can be 0.4% of an extracellular sodium single-quantum signal. This can be due to a low intracellular sodium concentration (e.g., 10% of the extracellular), a low MRI signal intensity usually achieved via triple-quantum filtering (TQF) (e.g., 10% of corresponding single-quantum signal), and a high level of random noise caused by a 6-step phase cycling used in TQF imaging. Second, a very long scan time (e.g., 40 min) can be needed due to a large specific absorption rate (SAR) during TQF imaging, which can be difficult to tolerate by patients under study.

The systems and methods of the present disclosure are directed to a generalized technique called multi-TE single-quantum (MSQ) sodium MRI (e.g., multi-TE single-quantum imaging). The technique can improve the accuracy of the mono-T₂ and bi-T₂ sodium separation in the framework of the short-T₂ imaging by replacing the subtraction with a matrix inversion. The short-T₂ imaging can be generalized to MSQ imaging to improve accuracy of the separation between mono- and bi-T₂ sodium signals by replacing the subtraction with a matrix inversion. To develop MSQ technique, the TEs can be optimized for data acquisition, the impact of T₂ values on accuracy of the separation can be investigated, and the mono-T₂ induction decay (FID) signals can be acquired to generate T₂* spectrum for the matrix equation. To test MSQ technique, computer simulations, physical phantom studies, and human studies can be implemented. The results from these studies can support the MSQ technique. Limitations of MSQ technique and potential pitfalls in interpretation of separated sodium signals can be itemized.

### Model of Sodium Signals

A two-population model can be used to describe single-quantum sodium signal m(t) evolving with time t at an imaging voxel ΔV.

$$m ( t ) = {m}_{mo} {Y}_{mo} ( t ) + {m}_{bi} {Y}_{bi} ( t ) , t \geq 0 \qquad Eq . 1 a$$

$${m}_{mo} \geq 0 , {m}_{bi} \geq 0 , and {m}_{mo} + {m}_{bi} = m ( 0 ) {Y}_{mo} ( t ) ≡ exp ( - t / {T}_{2 , mo} ) \qquad Eq . 1 b$$

$${Y}_{bi} ( t ) ≡ {a}_{bs} exp ( - t / {T}_{2 , bs} ) + {a}_{bl} exp ( - t / {T}_{2 , bl} ) \qquad Eq . 1 c$$

mₘₒ and m_{bi} are signal intensities proportional to volume fraction v_{q} times sodium concentration C_{q}, i.e., m_{q}∝ΔV(v_{q}C_{q}), q=mo and bi, for the mono-T₂ and bi-T₂ sodium populations in a voxel ΔV, respectively. Yₘₒ(t) is relaxation decay of the mono-T₂ sodium of time constant T_{2,mo}, and Y_{bi}(t) is relaxation decay of the bi-T₂ sodium with a_{bs}=0.6 (e.g., 60% of intensity) for the short-T₂ component (T_{2,bs}) and a_{bl}=0.4 (e.g., 40% of intensity) for the long-T₂ component (T_{2,bl}). The split of 60% vs. 40% in intensity can be from theoretical and experimental results for individual sodium nuclear spins. The T₂ values can be on the order of T_{2,bs}<<T_{2,bl}≤T_{2,mo}. Therefore, the model Eq. 1 may not include mono-T₂ sodium of short T₂.

### Separation of the Mono-T₂ and Bi-T₂ Sodium Signals

Given SQ sodium images acquired at multiple TEs, {TE₁, TE₂, . . . , TE_{N}}, Eq. 1a becomes a matrix equation in Eq. 2.

$$M = YX \qquad Eq . 2 a$$

$$M ≡ {( {m}_{1} , {m}_{2} , … , {m}_{N} )}^{T} , {m}_{i} = m ( {TE}_{i} ) , i = 1 , 2 , … , N \qquad Eq . 2 b$$

$$X ≡ {( {m}_{mo} , {m}_{bi} )}^{T} \qquad Eq . 2 c$$

Superscript T is the operator for matrix transpose. A solution to Eq. 2 can be given in Eq. 3 via an algorithm called non-negative least-squares (NNLS) in which a non-negative condition on X is automatically incorporated into the solution. Eq. 3 also represents intensity of the mono-T₂ and bi-T₂ sodium signals at TE=0.

$$X = NNLS ( YX - M ) \qquad Eq . 3$$

### Measurement of T₂ Values for the Separation of Mono-T₂ and Bi-T₂ Sodium Signals

The T₂ values (T_{2,mo}, T_{2,bs}, T_{2bl}) in Eqs. 1b and 1c can be used to perform the separation. They can be measured by acquiring FID signal s(t) on a whole imaging volume and using effective T₂ (i.e., T₂*) decay model of multi-exponential components to fit the FID signal in magnitude, for example, in Eq. 4.

$$\vert s ( t ) \vert = {\sum }_{j} {A}_{j} exp ( - T / {T}_{2 , j}^{*} ) \qquad Eq . 4$$

Hereinafter, T₂* replaces T₂ as spin echo may not be favorable to sodium MRI. The curve-fitting can be accomplished through the NNLS algorithm when T₂* values are pre-distributed in a range of interest [T₂*ₘᵢₙ, T₂*ₘₐₓ] at uniform or non-uniform intervals {ΔT_{2,j}*, j=1,2, . . . }. Amplitudes {Aⱼ}, called T₂* spectrum, can determine relative incidence of T₂* components in the imaging volume which counts all T₂* components from both mono-T₂ and bi-T₂ sodium populations. To pair up the short and long-T₂* components of the bi-T₂ sodium, the 60-40 split in intensity can be a helpful guideline.

Alternatively, empirical estimates of the brain tissues may be applicable to T₂* values because solutions to Eq. 2 are not so sensitive to T₂* values due to exponential decay.

FID signals may be acquired with an array coil, may have unique initial phases {φ_{0,l}, l=1,2, . . . , N_{c}} at individual coil elements, and may need to be aligned to produce a resultant FID signal. Alignment (e.g., via phase correction) can be towards a reference phase such as zero phase, one of the initial phases, or mean phase across elements. In addition, signal intensity at individual elements can be scaled via a so-called “FFT factor,” which can be stored in the header of a raw FID data file.

FID signals at the first few samples can be distorted by a hardware filter during analog-to-digital conversion (ADC). The number of affected samples can be in a range of 3-10 points, depending on sampling bandwidth, with the first sample having the largest distortion. This distortion can alter measurement of T₂* components, especially the short T₂* components which can be critically important to the bi-T₂ sodium. Correction for the distortion can be performed using an exponential extrapolation.

### Impact of T₂* Values on the Mono-T₂ and Bi-T₂ Sodium Separation

T₂* values can be measured at each of the individual voxels. However, the measurement can be time consuming and not favorable in clinical studies. A fast estimate would be beneficial. Solutions {mₘₒ, m_{bi}} to Eq. 1 may not be sensitive to T₂* values due to exponential decays in Eqs. 1b and 1c. This observation can be verified theoretically and numerically. Theoretically, small changes in T₂* values, {δT_{2,q}*, q=mo, bs, bl}, can lead to small changes in {δmₚ, p=mo, bi} in mₘₒ and m_{bi} under the same m(t), that is:

$$0 = δ ( {m}_{m o} {Y}_{m o} ) + δ ( {m}_{b i} {Y}_{b i} ) \qquad Eq . 5 a$$

$$- {m}_{δ} = {Y}_{m o} δ {Y}_{m o} + {y}_{b i} δ {Y}_{b i} \qquad Eq . 5 b$$

$$- {m}_{δ} ≡ {m}_{m o} δ {Y}_{m o} + {m}_{b i} δ {Y}_{b i} \qquad Eq . 5 c$$

$$δ {Y}_{q} = ( \frac{{tY}_{q}}{{T}_{2 , q}^{*}} ) ( \frac{δ {T}_{2 , q}^{*}}{{T}_{2 , q}^{*}} ) \leq {e}^{- 1} ( \frac{δ {T}_{2 , q}^{*}}{{T}_{2 , q}^{*}} ) , q = m o , b s , bl \qquad Eq . 5 d$$

$$δ {Y}_{b i} = {a}_{b s} δ {Y}_{b s} + {a}_{b l} δ {Y}_{b l} \leq {e}^{- 1} [ {a}_{b s} ( \frac{δ {T}_{2 , bs}^{*}}{{T}_{2 , bs}^{*}} ) + {a}_{b l} ( * \frac{δ {T}_{2 , bl}^{*}}{{T}_{2 , bl}^{*}} ) ] \qquad Eq . 5 e$$

where δ is difference operator. Eq. 5b can quantify errors in mₘₒ and m_{bi} caused by estimation error in the T₂* values.

Numerically, errors in mₘₒ and m_{bi} can be calculated, given a series of {T_{2,q}*, δT_{2,q}*; q=mo, bs, bl} at a specific pair of (mₘₒ, mₚᵢ). This can be used to create a plot showing how the computed (mₘₒ, m_{bi}) change with {δT_{2,q}*; q=mo, bs, bl}.

### Optimalization of the Number of TEs

In principle, the more TEs, the better differentiation between the T₂* relaxations of the mono-T₂ and bi-T₂ sodium populations, and the better solutions to Eq. 2. In practice, the number of TEs can be restricted by total scan time (TA), SNR, signal decay, and risk of motion artifacts across TEs. Therefore, a trade-off may be made for the number of TEs. To determine an optimal number of TEs, noise propagation in Eq. 2 can be understood. Let singular value decomposition (SVD) of the matrix Y in Eq. 2a be:

$$Y = U \sum {V}^{T} \qquad Eq . 6 a$$

$$\sum = diag ( {σ}_{1} , {σ}_{2} ) \qquad Eq . 6 b$$

$$X = V {\sum }^{- 1} {U}^{T} M \qquad Eq . 6 c$$

Singular values (σ₁, σ₂) can determine noise transfer (e.g., amplification or suppression) in Eq. 6c from the measured TE-images M to the separated mono-T₂ and bi-T₂ sodium images X.

However, Eq. 6c can allow negative values in solution X when random noise contaminates data M. This can violate the “non-negative” condition on X. Therefore, SVD analysis can be applicable only to X elements with SNR≥2 where X elements with Gaussian noise have 95.4% of chance in the territory of non-negative value.

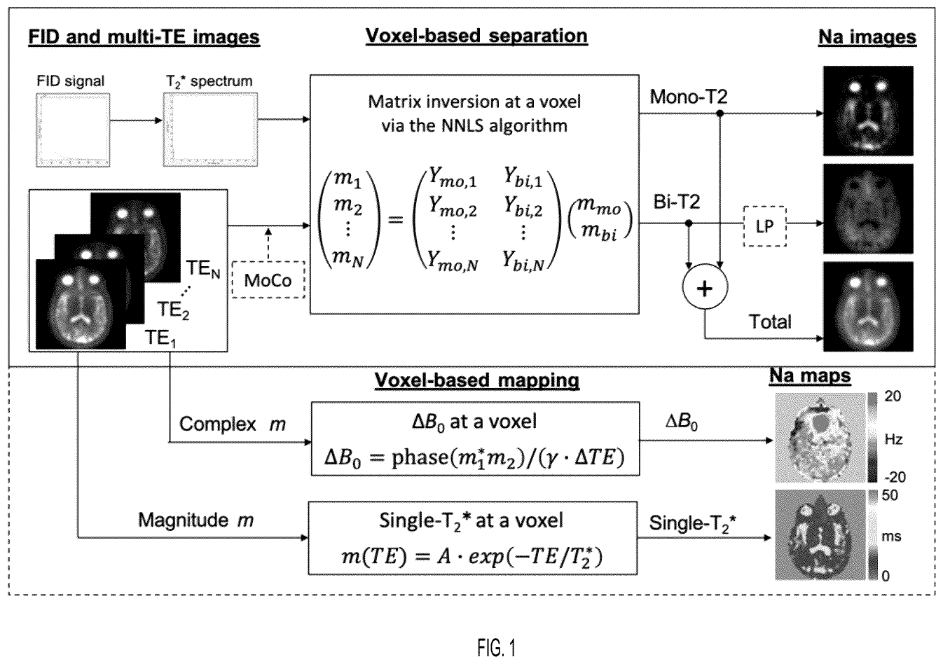

The MSQ technique is graphically illustrated in FIG. 1. The inputs can be multiple TE images and an FID signal. The outputs can be the mono-T₂, bi-T₂, and total sodium images, as well as the maps of field inhomogeneity ΔB₀ and single-T₂*. In between can be the data processing functionalities for T₂* spectrum, mono-T₂ and bi-T₂ sodium separation, and mapping of ΔB₀ and single-T₂*. Motion correction (MoCo) across multi-TE SQ images can be optional. The low-pass (LP) filtering, which is a 3D averaging over a size of 3×3×3 voxels for instance, to reduce random noise on the bi-T₂ sodium, can be optional. The ΔB₀ and single-T₂* maps can present spatial distributions of the B₀ field inhomogeneity and the short-T₂* and long-T₂* components, and can provide indications for uncertain short-T₂* decays possibly caused by the B₀ inhomogeneity. These maps can be critical and complimentary to quantification and explanation of the separated mono-T₂ and bi-T₂ sodium signals.

FIG. 1 illustrates a flowchart 100 of the multi-TE single-quantum (MSQ) sodium MRI technique. The input can include multi-TE SQ images M(TE) and an FID signal producing T₂* spectrum. Motion correction between SQ images is optional and used if necessary. The separation can include matrix inversion voxel-by-voxel across the field-of-view (FOV). The output can include three sodium images (mono-T₂ Mₘₒ, bi-T₂ M_{bi}, and total Mₘₒ+M_{bi}). The low-pass (LP) filtering is a 3D smoothing of size 3×3×3 or others and is optional to further reduce random noise. Additional outputs can include the maps of B₀ inhomogeneity and single-T₂*, which can provide complimentary information for the quantification and interpretation on the mono-T₂ and bi-T₂ sodium images.

Computer software can implement the MSQ technique. The numerical simulations can be performed in MATLAB. Random noise of Gaussian distribution can be generated using MATLAB function randn(n), while the NNLS algorithm can be implemented using [x, resnorm, residual]=lsqnonneg(C, d).

### Measurement of T₂* Values

FID signals can be acquired on the whole brain of the study subjects right before sodium imaging. A product pulse sequence, either AdjXFre embedded in the manual shimming task or independent fid_23Na, can be employed with the following parameters: TE=0.35-1.0 ms, TR=100-300 ms, and averages=1-128, TA=0.2-39 s. When a dual-tuned (¹H-²³Na) 8-channel Tx/Rx head array coil is used, there can be a difference in initial phase and in FFT scale factors across channels. The initial phase of an individual channel can be measured on the channel image at the central slice and be removed by aligning to the zero phase. The initial phases can be measured on channel image at central slice, and removed by aligning to zero phase. Channel signals (e.g., channel FID signals) can be weighted with FFT scale factors and complex-values combined into a resultant FID signal. An additional step can be performed to correct for distortion at the first few points of the resultant FID signal caused by ADC hardware filter. A spectrum of T₂* values can be calculated according to Eq. 4, at a resolution of 0.5 ms for T₂* in a range of 0.5-100 ms. Assignment of T₂* peaks to {T_{2,mo}*, T_{2,bs}*, T_{2,bl}*} can be based on their relative positions and intensities, i.e., T_{2,mo}*≥T_{2,bl}*>>T_{2,bs}*, and intensity ratio 6:4 for the bi-T₂ sodium.

### Sensitivity to T₂* Values

As a testing point in this simulation, a set of T₂* values, {T_{2,mo}*, T_{2,bs}*, T_{2,bl}*}={50.0, 3.5, 15.0} ms, which can be commonly encountered in human brains studies, can be employed. Then, an error of δT_{2,q}*; q=mo, bs, bl, in a range of ±20% can be added to the testing T₂* values, which can serve as the estimated T₂* values. Finally, {mₘₒ, m_{bi}} and their errors {δmₘₒ, δm_{bi}} relative to the true values in a range of 0.1<m_{fr}≤0.9, can be calculated according to Eq. 3. The relationships between {δmₘₒ, δm_{bi}} and {δT_{2,q}*; q=mo, bs, bl} can be plotted to illustrate these changes. To focus on the relation “δT₂*−δm”, TEs can be sampled in an ideal case where the initial TE was zero (TE₀=0) at an interval of 1.0 ms (ΔTE=1 ms) and 80 TEs covering the entire T₂* decays.

### Optimization of TEs

The simulations can be implemented via Eq. 6 for three cases: an ideal case serving as reference, practical case 1 having a large number of TEs, and practical case 2 having a small number of TEs. The ideal case can have 80 TEs, i.e., TE=(0, 1, 2, . . . , 79) ms, to cover entire range of the T₂* decays. The two practical cases, suggested by human studies, can have total scan time (TA) limited to 22 min for 8 TE-images, and the distribution of TEs can be chosen such that it was most sensitive to T₂* decays. Thus, case 1 can have 8 TEs (i.e., TE=(0.5, 1, 2, 3, 4, 5, 7, 10) ms), while case 2 can have two TEs (i.e., TE=(0.5, 5.0) ms) but 4 averages at each TE. The SVD singular values (σ₁≥σ₂≥0) can be calculated for each set of TEs via Eq. 6. The optimal set of TEs can be the one that had a σ₂ value producing the minimum amplification of random noise in the separated mono-T₂ and bi-T₂ sodium images.

### Computer Simulations

The mono-T₂ and bi-T₂ sodium separation can be carried out via Eq. 3 at a typical set of T₂ values, (T_{2,mo}*, T_{2,bs}*, T_{2,bl}*)=(50.0, 3.5, 15.0) ms, under a two-TE acquisition scheme, TE=(0.5, 5.0) ms. Sodium signals can be calculated via Eq. 1, with an additive Gaussian noise, N(0, σ²), at each of noise trials (independent from each other), m(t)+n(t). The mono-T₂ and bi-T₂ signal amplitudes {mₘₒ, m_{bi}} can be simulated to vary in a normalized range of 0.0-1.0 at a step size=0.1. The separation can be implemented via Eq. 3 using the function lsqnonneg( ) in MATLAB, and repeated Nₙₒᵢₛₑ times at each of the specific amplitudes. The mean and standard deviation (SD) can be reported as separated sodium signal. Nₙₒᵢₛₑ=1054 can be chosen to detect a 10% of SD, or 0.1 effect size d=Δμ/SD, in difference between the mean and true value at 90% power and 5% significant level under the two-sided Student's t-test.

### Phantom Studies

Four phantoms can be studied. They can include 50 mL centrifuge tubes filled with a mixture of distilled water, 10% w/w agar powder, and sodium chloride (NaCl) at three concentrations ranging from 90-150 mM (e.g., 90 mM, 120 mM, and 150 mM), mimicking mono-T₂ and bi-T₂ sodium signals in the brain tissues. Sodium MRI can be performed on a clinical scanner at 3T with a dual-tuned (¹H-²³Na) volume head coil. The data acquisition can be implemented using an SNR-efficient, 3D pulse sequence called the twisted projection imaging (TPI), with parameters: rectangular RF pulse duration=0.8 ms, flip angle=80° (limited by SAR and TR), field of view (FOV)=220 mm, matrix size=64, nominal resolution=3.44 mm (3D isotropic), TPI readout time=36.32 ms, total TPI projections=1596, p-factor=0.4, TR=100 ms, TE₁/TE₂=0.5/5 ms, averages=4, and TA=10.64 min per TE-image. The image reconstruction can be offline implemented on a desktop computer using a custom-developed programs in C++. Separation of the mono-T₂ and bi-T₂ sodium signals can be implemented using a custom-developed program.

### Human Studies

The human studies can be conducted with the approval of local Institutional Review Board (IRB). The study subjects of the human studies can include nine healthy adults (age 39.6±21.4 years between 21-74 years; 3 males and 6 females) and six patients with neurological disorders (1 with bipolar disorder, 3 with epilepsy, 1 with multiple sclerosis, and 1 with mild traumatic brain injury; age 30.5±15.1 years between 18-59 years; 3 males and 3 females). The study can be performed on a clinical 3T MRI scanner with a custom-built 8-channel dual-tuned (¹H-²³Na) head array coil. The same TPI pulse sequence as in the phantom studies can be used for data acquisition. Images can be reconstructed using the gridding algorithm, off-line and channel-by-channel, and combined into a resultant image via the sum-of-squares (SOS) algorithm. To decouple random noise across channels, an orthogonal linear transform can be performed in which physical channel data can be transformed into virtual channels with random noise independent from channel to channel. This decoupling and denoising process can also normalize signal amplitudes across channels by dividing noise standard deviation. Separation of the mono-T₂ and bi-T₂ sodium signals can be implemented in the same way as in the phantom studies.

### Mapping of ΔB₀ and Single-T₂

To map ΔB₀ (or Δf₀=γΔB₀/2π), the Hermitian product method can be performed via Eq. 7 at individual imaging voxels to calculate phase differences {Δφᵢ, i=1,2, . . . , N-1} between TEs {TEᵢ, i=1,2, . . . , N}. Image amplitude at individual channels can be corrected with the FFT factors {wₗ, l=1,2, . . . , N_{c}}. Phase unwrapping may not be performed due to small intervals in the TEs and, in general, small inhomogeneity in the B₀ field in sodium MRI. Computation for ΔB₀ map can be fast (0.078 s) on a laptop computer for images of size 64×64×64 at two TEs.

$$Δ {f}_{0} = \frac{1}{2 π ( N - 1 )} {\sum }_{i = 1}^{N - 1} {Δφ}_{i} / Δ {TE}_{i} \qquad Eq . 7 a$$

$${Δφ}_{i} = phase \{ {\sum }_{l = 1}^{{N}_{c}} {w}_{l}^{2} \cdot {m}_{l}^{*} ( {TE}_{i} ) \cdot {m}_{l} ( {TE}_{i + 1} ) \} \qquad Eq . 7 b$$

$$Δ {TE}_{i} = {TE}_{i + 1} - {TE}_{i} \qquad Eq . 7 c$$

To map single-T₂*, a MATLAB curve-fitting function fit(x, y, ‘exp1’) can be used to calculate single-T₂* values at each voxel via Eq. 8. A restriction (T_{2,max}*<100 ms) can be enforced to exclude unreasonable values caused by noise. Computation time for the single-T₂* mapping can be acceptable (10 min 17 s).

$$\vert m ( T {E}_{i} ) \vert = {A}_{i} exp ( - {TE}_{i} / {T}_{2}^{*} ) , 0 \leq {T}_{2}^{*} \leq {T}_{2 , max}^{*} \qquad Eq . 8$$

### Signal-to-Noise Ratio

In a region of interest (ROI), SNR can be calculated via Eq. 9 in a simplified way for both volume and array coils by taking the ratio of mean intensity S to noise standard deviation (SD) in noise-only background regions. A factor of 0.655 can be applied to noise SD to account for Rician distribution in magnitude images. For SNR mapping, pixel signal is used in the calculation.

$$SNR = 0.6 \; 55 S / SD \qquad Eq . 9$$

### Estimation of Extra- and Intracellular Volume Fractions

The estimates can give the upper-limit of volume fractions when all the mono-T₂ sodium are assigned to extracellular space while the bi-T₂ sodium to intracellular space, in the case that mono-T₂ and bi-T₂ sodium may co-exist in both extracellular and intracellular spaces. The estimates were made in ROIs of the gray and white matters via Eq. 10a-10c at the concentrations Cₑₓ=145 mM for extracellular and Cᵢₙ=15 mM for intracellular spaces.

$${V}_{e x} = 1 / ( 1 + a ) \qquad Eq . 10 a$$

$${V}_{i n} = a / ( 1 + a ) \qquad Eq . 10 b$$

$$a ≡ {m}_{b i} {C}_{e x} / {m}_{m o} {C}_{i n} \qquad Eq . 10 c$$

### Statistical Significance

A regular statistical significance (P=0.05) can be applied to the comparisons, via Student's t-test, between the two sets of data. The minimum sample size for the t-test can be 16, with 80% power, 5% significance level, two-sided test, and 1.0 effect size.

### Measurement of T₂* Values

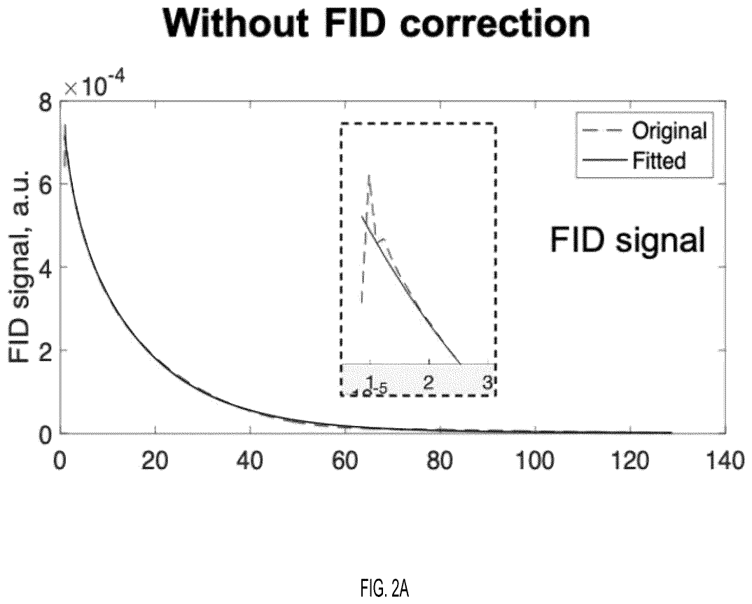

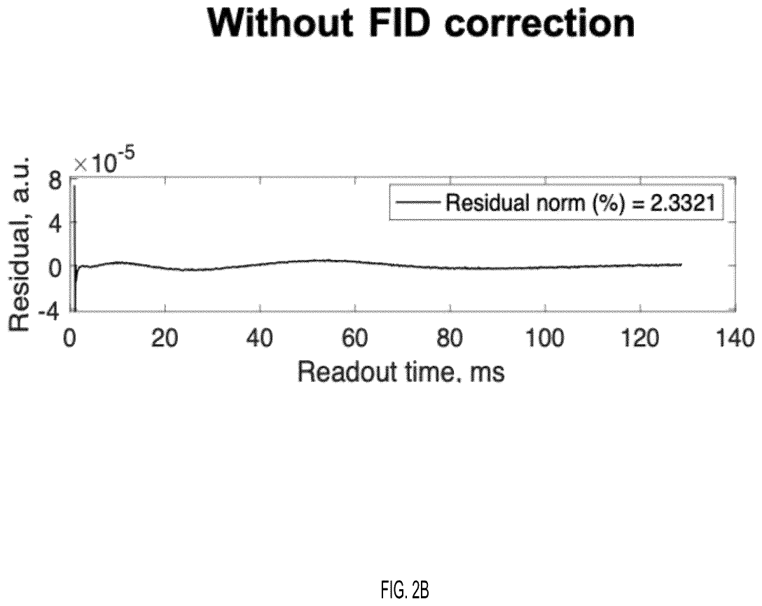

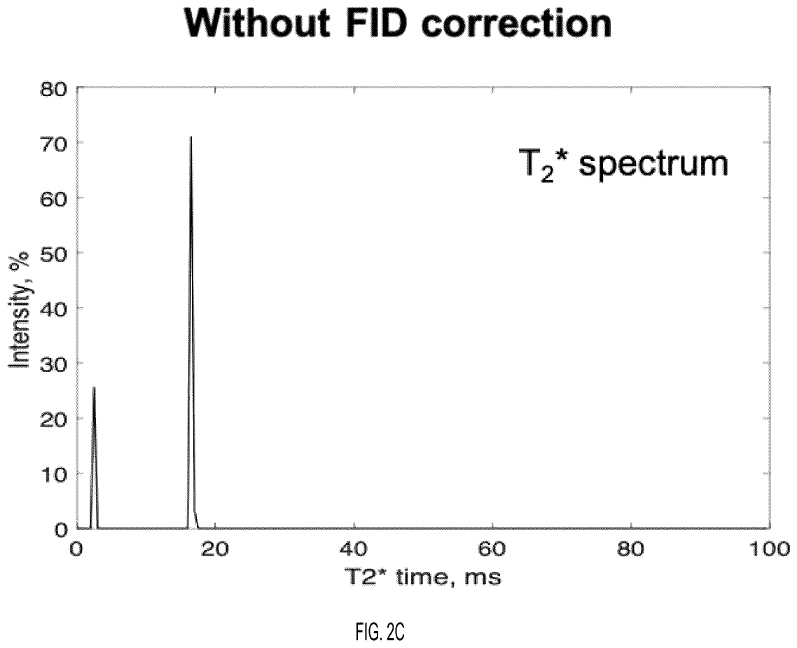

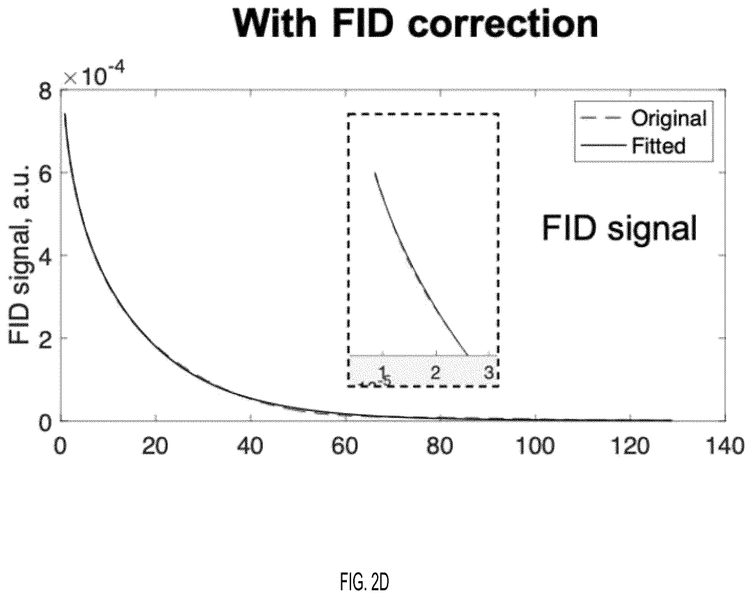

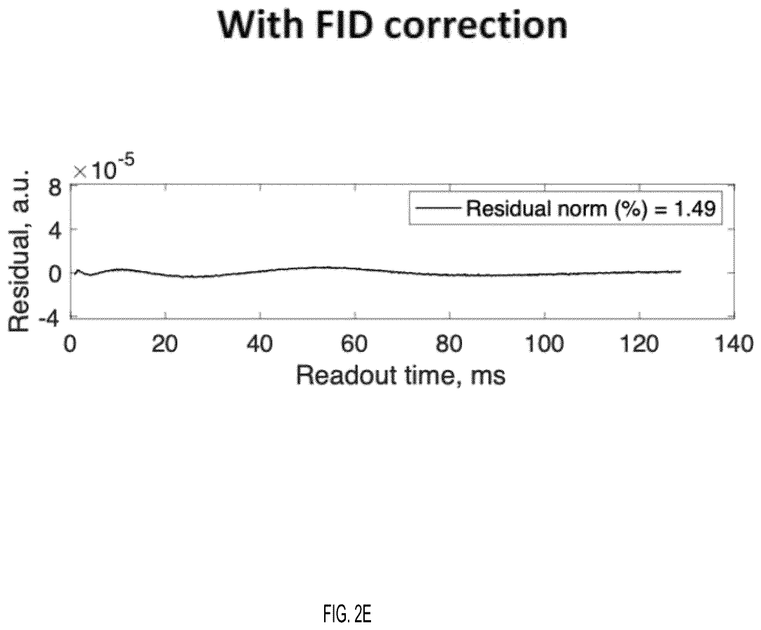

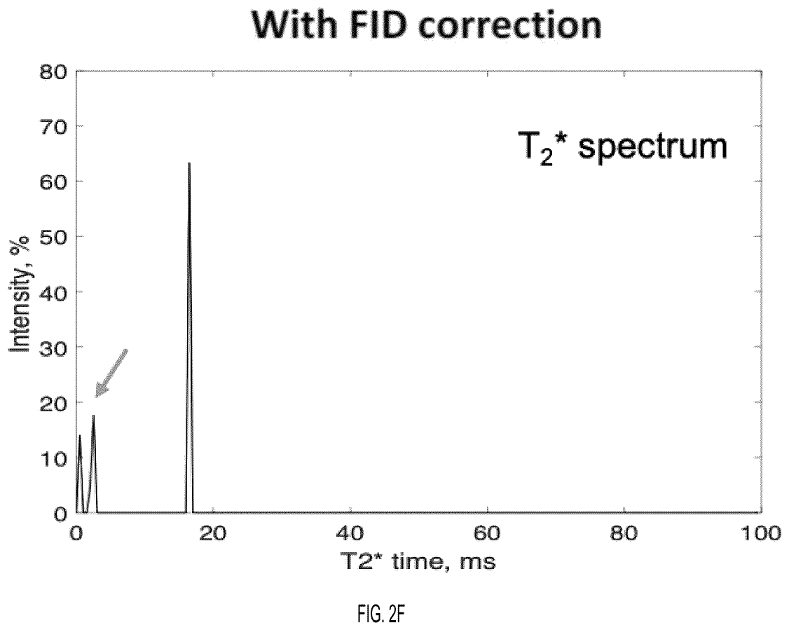

A representative measurement of T₂* values on a healthy subject (52 years old, male) is demonstrated in FIGS. 2A-2F. Data acquisition can be performed on a 3T MRI scanner with a custom-built dual-tuned (¹H-²³Na) 8-channel head array coil using a product sequence fid with parameters: rectangular RF pulse=0.5 ms, flip angle=90°, TE/TR=0.35/300 ms, averages=128, ADC samples=1024 at sampling interval Δt=0.125 ms. The FID signal from the whole brain can be fitted into T₂* spectrum, with and without correction for the distortion at the first five ADC samples (FIGS. 2A, 2D). The correction can effectively remove distortion and can significantly reduce overall residual fitting error from 2.33% to 1.49% (FIGS. 2B, 2E). The correction can also improve resolution of short-T₂* components from singlet at 2.5 ms to doublet at 0.5 ms and 2.5 ms (FIGS. 2C, 2F). A high resolution in T₂* can be achieved at 0.5 ms, with residual fitting error less than 1.5%. A few of sparse peaks can appear in the T₂* spectrum, indicating that T₂* values can be well clustered in the human brain and that a single set of T₂* values can be applicable to the separation of mono-T₂ and bi-T₂ sodium. Data acquisition: 3T scanner with a custom-built dual-tuned (¹H-²³Na) 8-channel head array coil, FID sequence, RF=0.5 ms, TE/TR=0.35/300 ms, averages=128, ADC samples=1024 at a sampling interval dt=0.125 ms.

### Sensitivity to T₂* Values

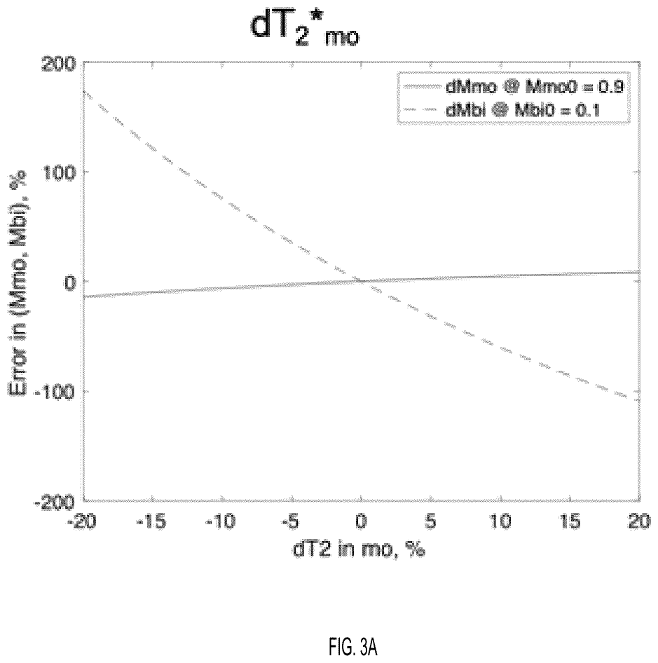

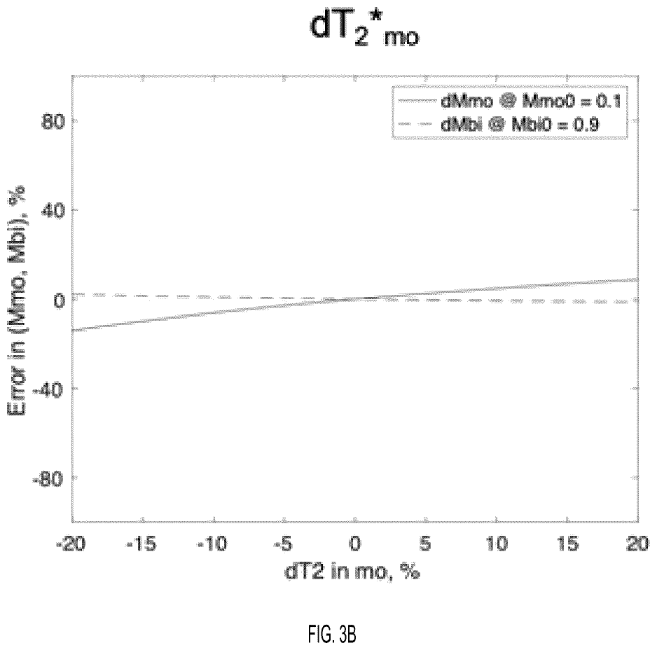

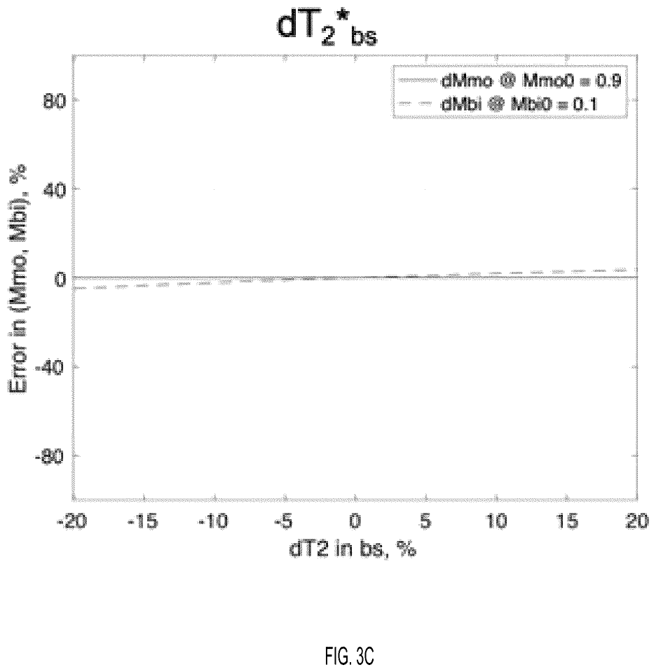

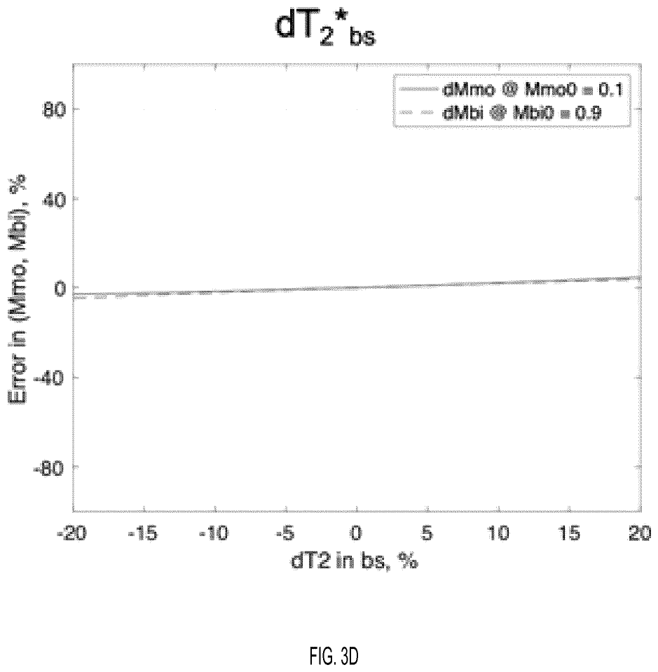

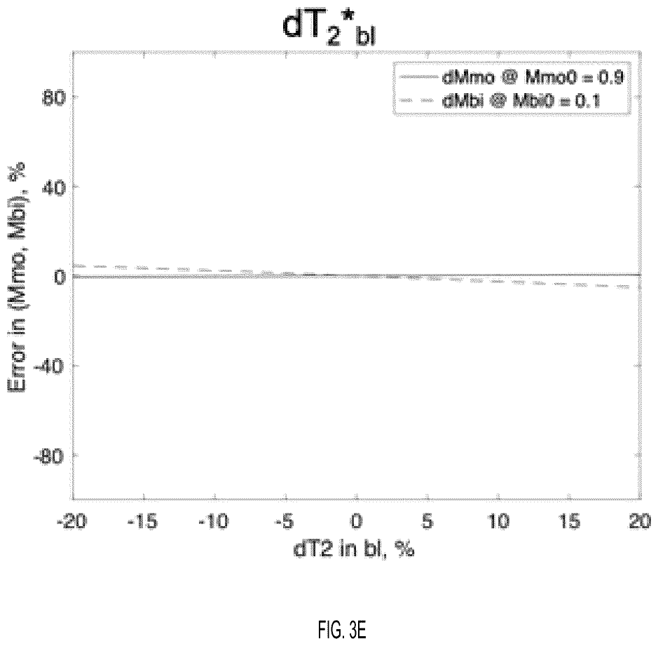

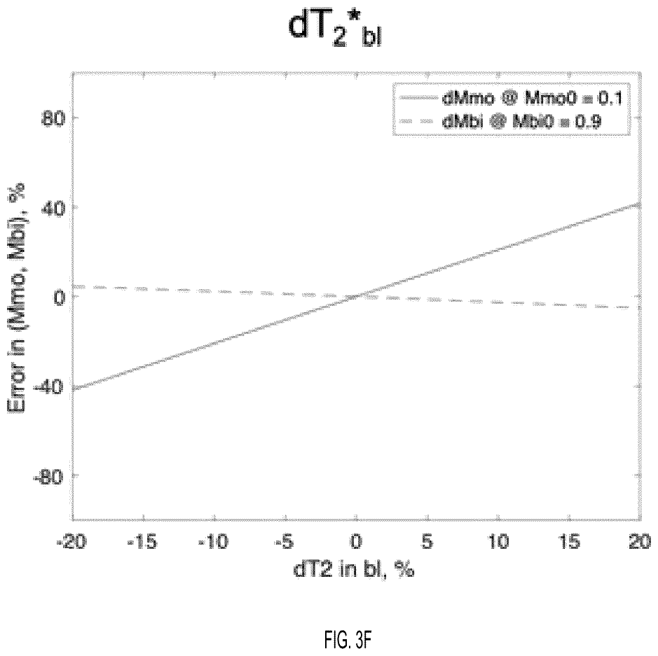

FIGS. 3A-3F illustrate simulated impact of estimated T₂* values on the separation of mono-T₂ and bi-T₂ sodium signals (Mₘₒ, M_{bi}) at a typical set of (T_{2,mo}*, T_{2,bs}*, T_{2,bl}*)=(50.0, 3.5, 15.0) ms in two extreme cases: the mono-T₂ sodium dominating (FIGS. 3A, 3C, 3E), Mₘₒ=0.9, and the bi-T₂ sodium dominating (FIGS. 3B, 3D, 3F), M_{bi}=0.9. In the columns are the impact of individual T₂* components. FIGS. 3A and 3B show an error in T_{2,mo}* produced an error in Mₘₒ or M_{bi} much smaller for the dominant one (e.g., ΔM_{bi}<2.2% when T_{2,mo}*<20%, and ΔMₘₒ<2.9% when T_{2,mo}*<5.0%). FIGS. 3C and 3D show an error in T_{2bs}* had a small impact on both Mₘₒ and M_{bi} (e.g., when dominating, ΔM_{bi}<4.8% and ΔMₘₒ<0.02% when T_{2,bs}*<20%). FIGS. 3E and 3F show an error in T_{2,bl}* led to an error in Mₘₒ or M_{bi} much smaller for the dominant one (e.g., ΔM_{bi}<5.2% and ΔMₘₒ<0.6% when T_{2,bl}*<20%). The best case is FIGS. 3C and 3D, where the T_{2,bs}* had small impact (<4.9%) on both mono-T₂ and bi-T₂ sodium signals. The worst case is FIG. 3A, where the T_{2,mo}* had a large impact on the bi-T₂ sodium signal, ΔM_{bi}=35.6% when T_{2,mo}*=−5%. In other words, when the mono-T₂ sodium is very dominating, T_{2,mo}* value should be as accurate as possible to attain a separation (e.g., best separation) for the bi-T₂ sodium.

### Optimization of TEs

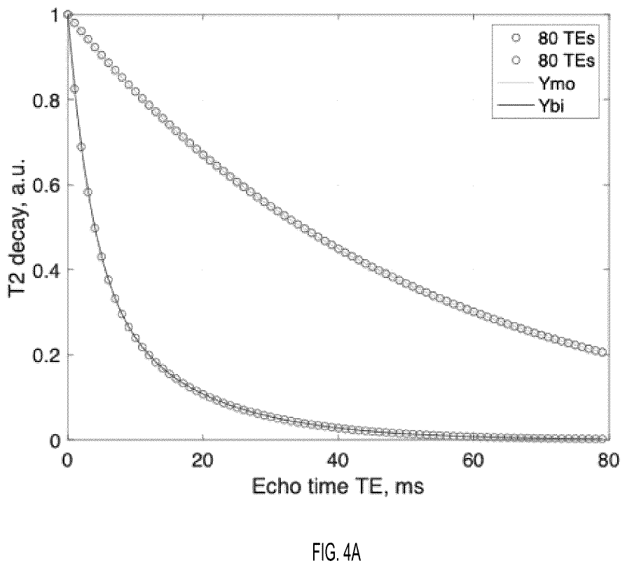

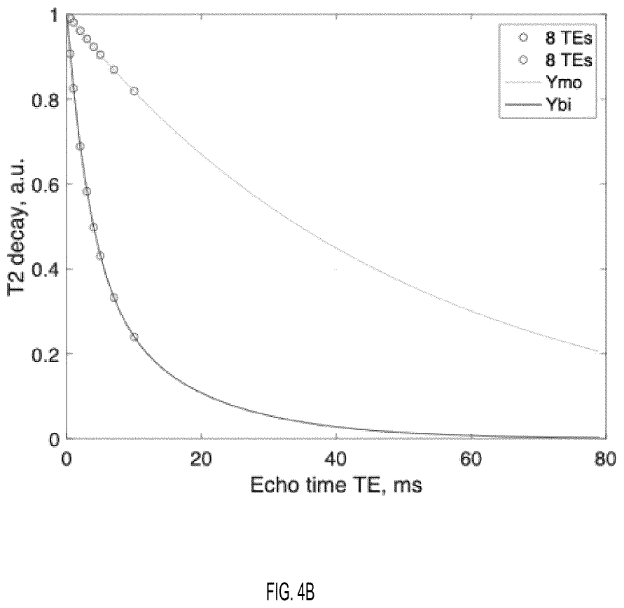

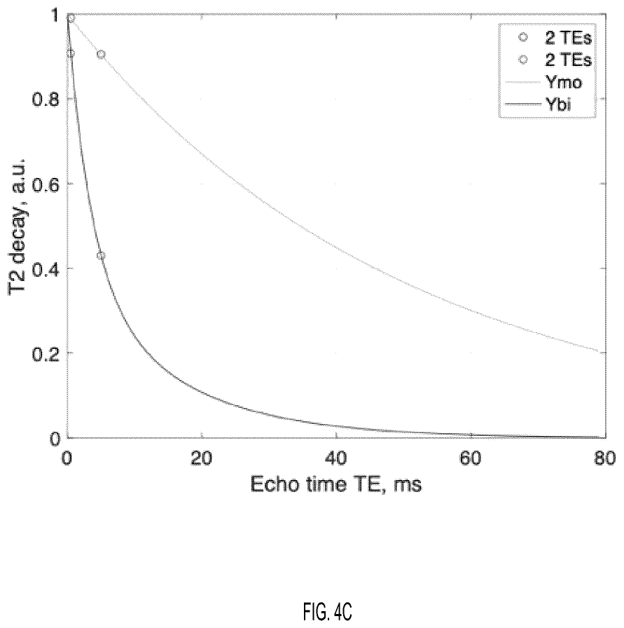

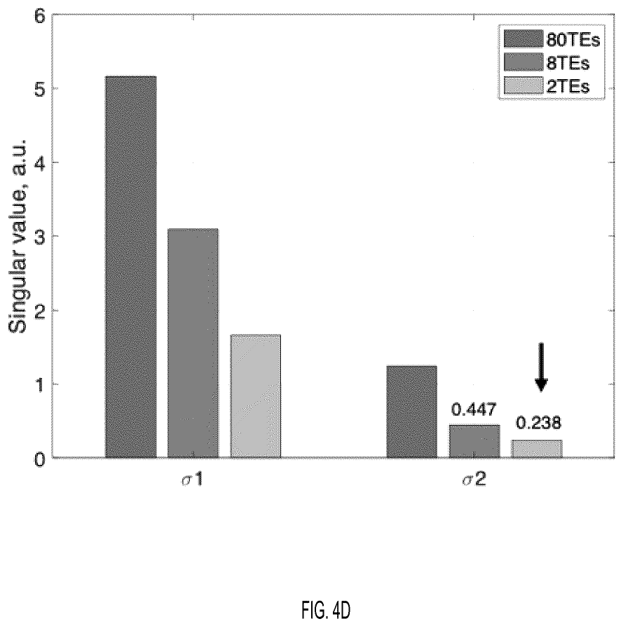

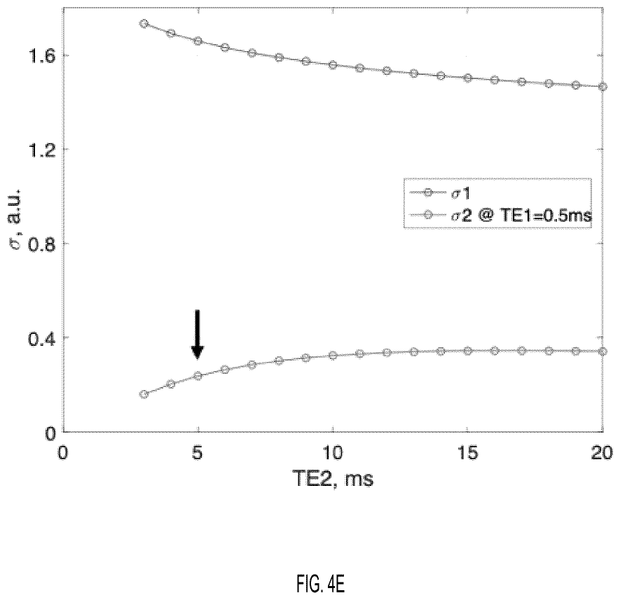

FIGS. 4A-4E demonstrate the optimization of TE sampling schemes and scheme optimization via the singular value decomposition (SVD) singular values. As reference, an ideal scheme of 80 TEs, which can be in a range of 0-79 ms at an interval of 1 ms, is presented in FIG. 4A on a mono-exponential T₂* decay Y_{fr}(TE) of the mono-T₂ sodium at a typical value T_{2,mo}*=26 ms and on a bi-exponential T₂* decay Y_{bi}(TE) of the bi-T₂ sodium at a typical set {T_{2,bs}*, T_{2,bl}*}={3.5, 15.0} ms. An intuitively favorable scheme of 8 TEs at {0.5, 1, 2, 3, 4, 5, 7, 10} ms was presented in FIG. 4B, while an optimal candidate of two TEs at {0.5, 5} ms was presented in FIG. 4C. Singular values (σ₁, σ₂) of the three schemes were compared against each other in FIG. 4D. In addition, singular values of the two-TE scheme can show a slow change with the second TE increasing (FIG. 4E). In contrast to σ₁, σ₂ can be less than 1.0 for all the three schemes, leading to an amplification of noise. Thus, a better choice for less noise amplification can be the two-TE scheme, in which TE₂ at 5 ms produced a value near maximum for σ₂ while preserving higher signal than the larger TE₂. Thus, the two-TE scheme can represent an optimal one for the human studies (e.g., human brain studies).

### Computer Simulations

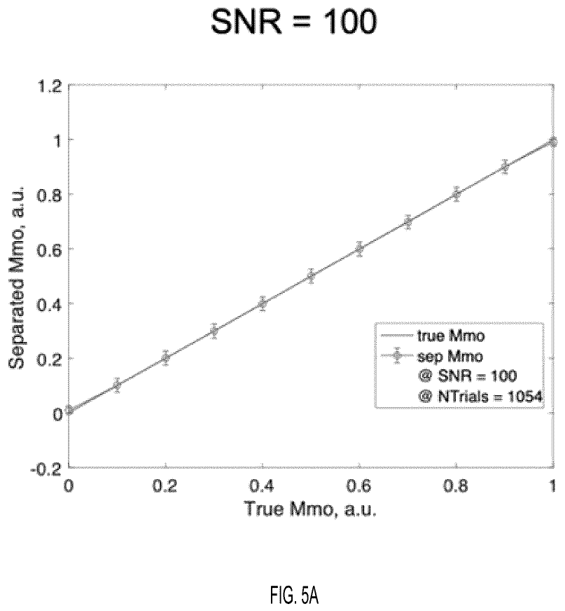

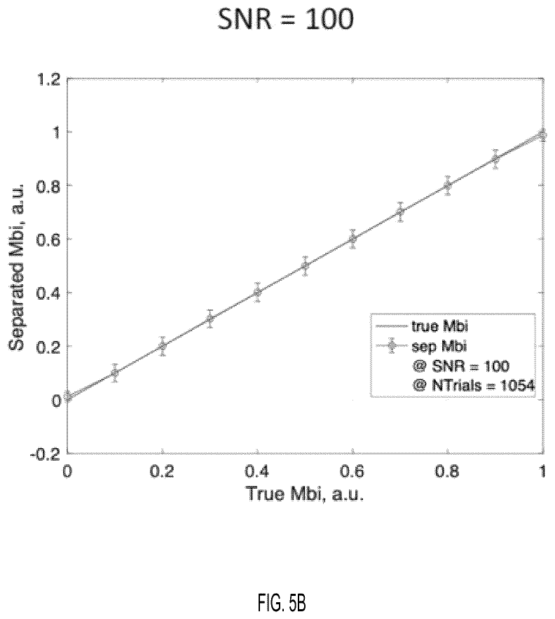

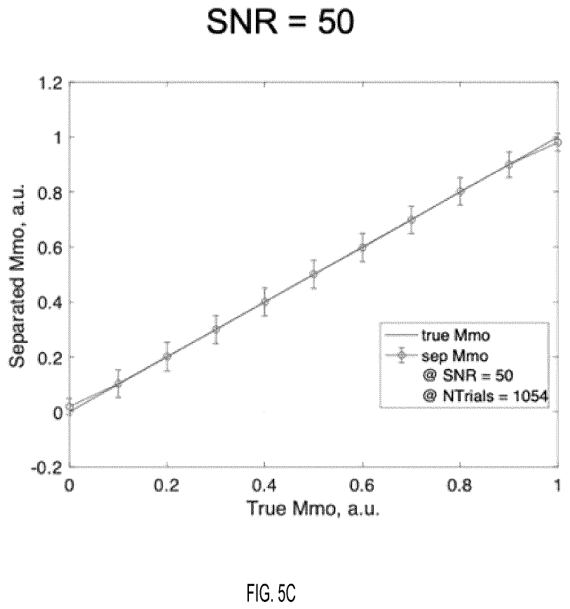

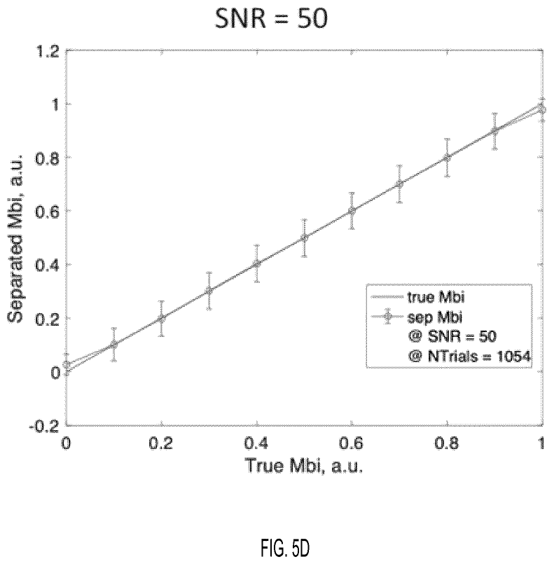

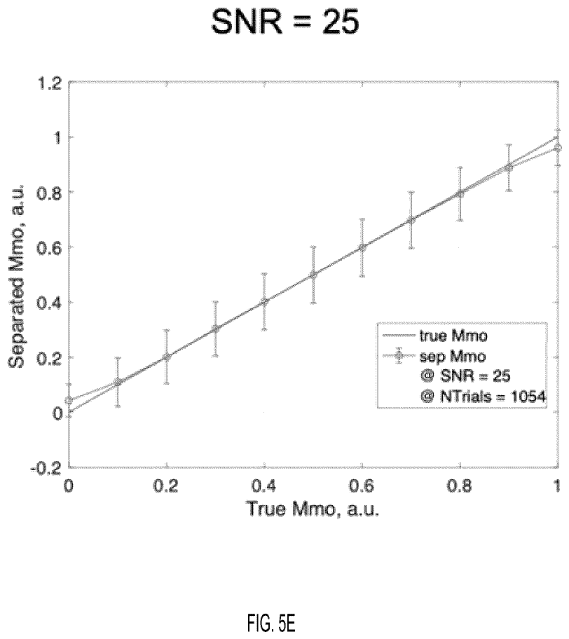

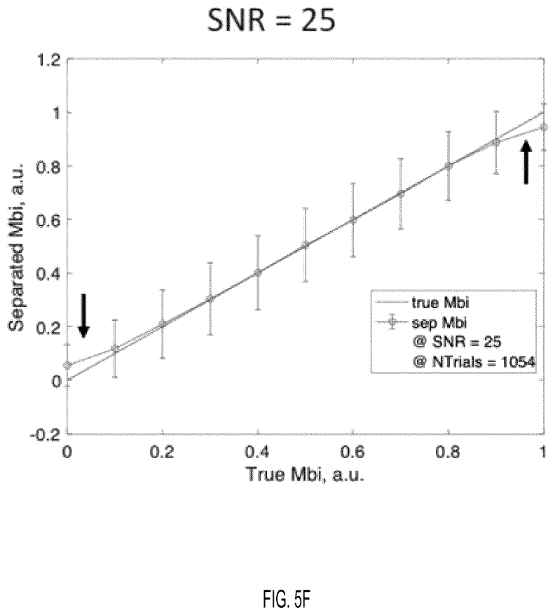

FIGS. 5A-5F demonstrate the simulated separation of the mono-T₂ and bi-T₂ sodium signals (Mₘₒ, M_{bi}) at a typical set of (T_{2,mo}*, T_{2,bs}*, T_{2,bl}*)=(50.0, 3.5, 15.0) ms and two-TE scheme TEs=(0.5, 5.0), at three SNRs: extra-high (SNR=100) (FIGS. 5A and 5B), high (SNR=50) (FIGS. 5C and 5D), and regular (SNR=25) (FIGS. 5E and 5F). The mean and standard deviation (SD) of the separated Mₘₒ (FIGS. 5A, 5C, 5E) and M_{bi} (FIGS. 5B, 5D, 5F) were presented. The SD (error bar) consistently decreased with SNR increasing. There was an underestimate (arrow) for Mₘₒ or M_{bi} near the maximum value (1.0), but an overestimate (arrow) near the minimum value (0.0), with an amount decreasing with SNR increasing.

### Phantom Studies

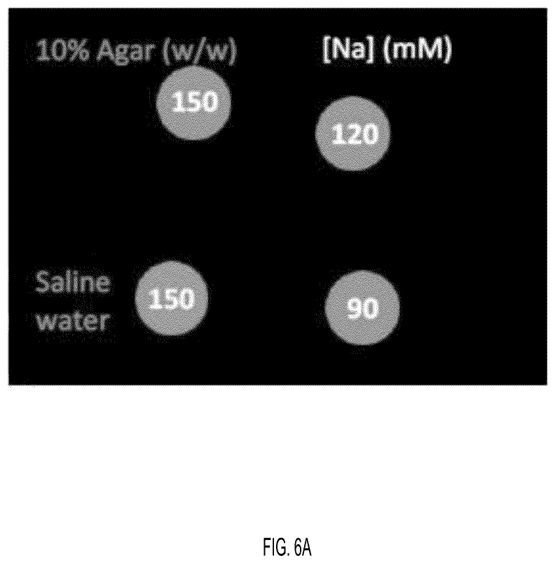

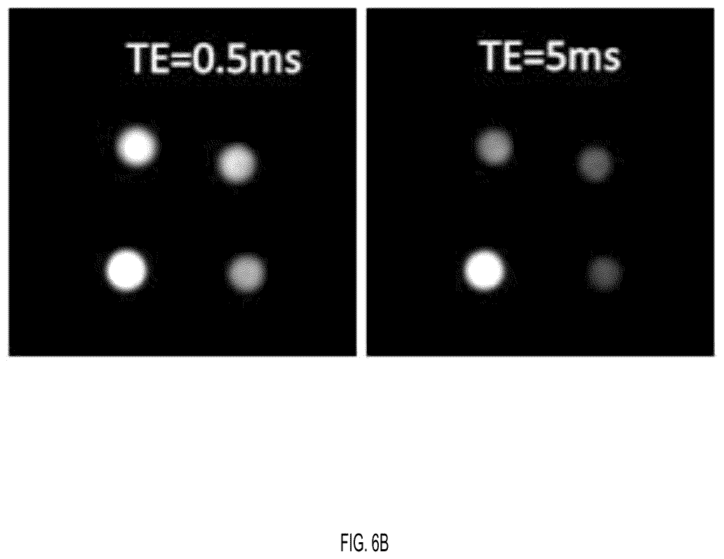

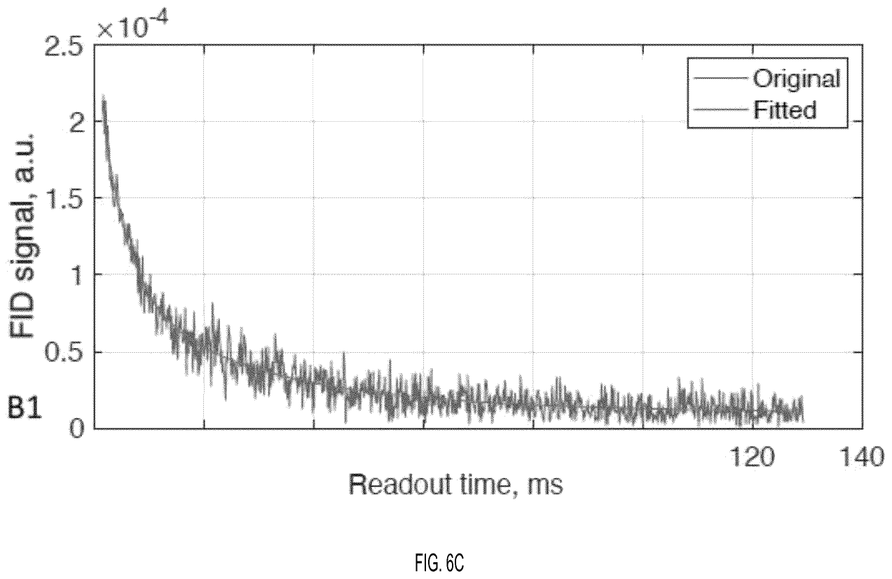

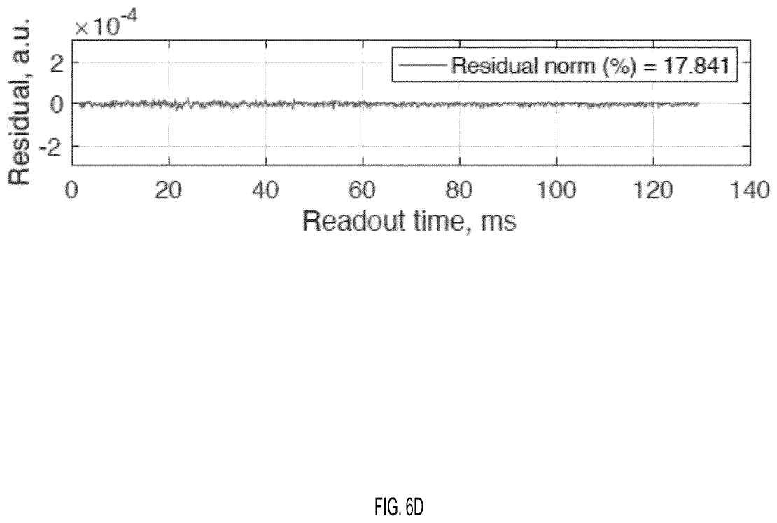

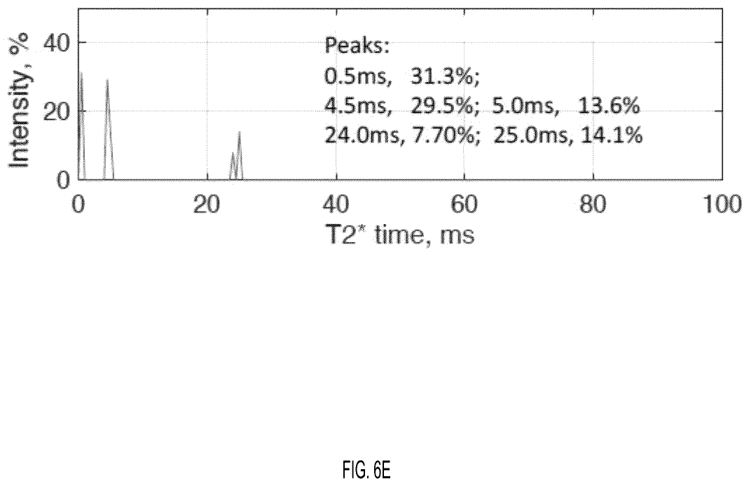

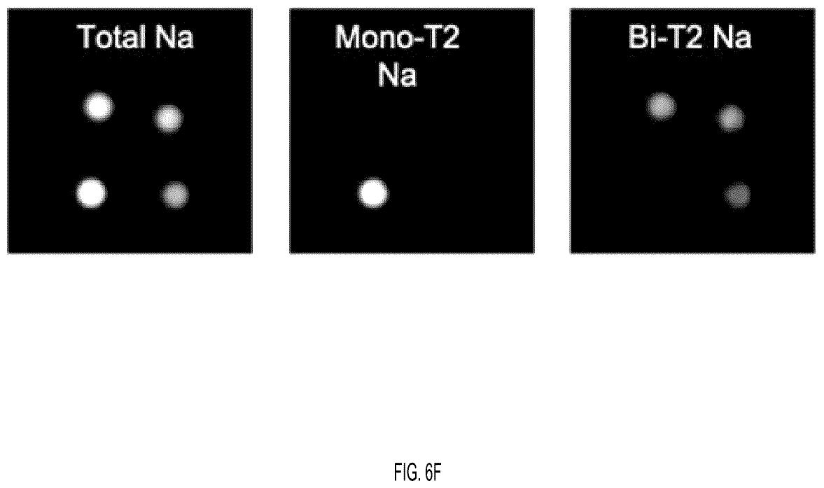

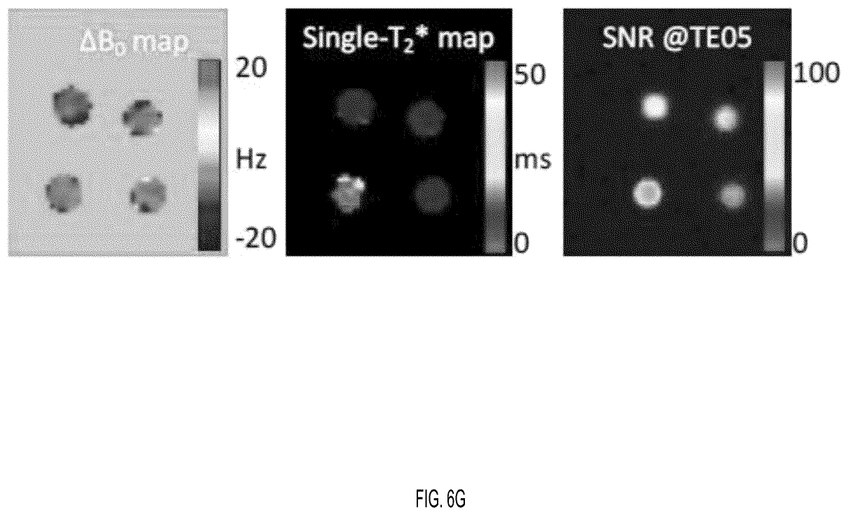

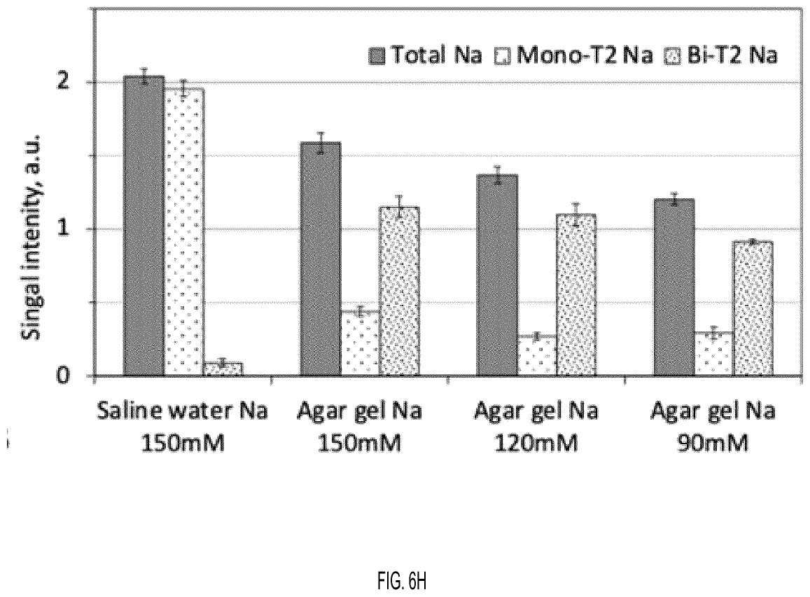

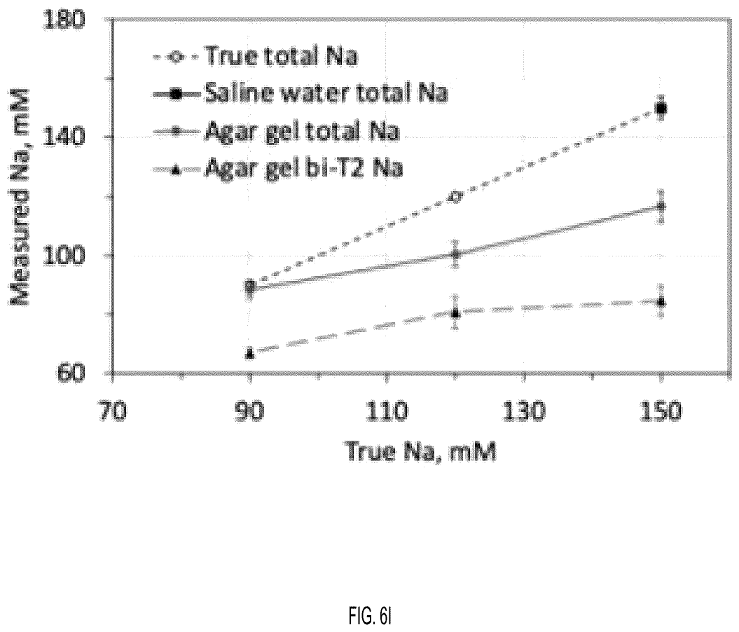

FIGS. 6A-6I illustrate the results of a phantom study. FIG. 6A shows a phantom of four tubes with sodium concentration: 150 mM for the saline water and 90-150 mM for the agar gels. FIG. 6B shows sodium images of the phantoms at TE₁/TE₂=0.5/5 ms, shown in the same window/level. FIG. 6C shows FID signals (original and fitted) from the four tubes at averages=1, with the correction for distortion at the first five data points. FIG. 6D shows residual error of the fitting in FIG. 6C. FIG. 6E shows T₂* spectrum calculated from the original FID in FIG. 6C and used to produce the fitted FID. FIG. 6F is sodium images (total, mono-T₂, and bi-T₂) separated from the two images in FIG. 6B at (T_{2,mo}*, T_{2,bs}*, T_{2,bl}*)=(50, 5, 25) ms according to FIGS. 6E and 6G. FIG. 6G shows maps of ΔB₀ and single-T₂* calculated from the two images in FIG. 6B and a map of SNR at TE=0.5 ms. FIG. 6H shows separated sodium signals (mean±SD) in the tube regions in FIG. 6F. FIG. 6I shows quantified sodium concentration from FIG. 6H.

The separation in FIG. 6H recovered 95.8% of mono-T₂ sodium signal in the saline water tube, while leaving 4.2% to bi-T₂ sodium signal (much better than 20% left by the subtraction approach). The separation recovered 72.5, 80.4, and 75.9% of bi-T₂ sodium signal in the agar tubes at sodium concentrations of 150, 120, and 90 mM, respectively. The quantification of sodium concentration in FIG. 6I, when calibrated at the saline water, can show a systematic bias in total and bi-T₂ sodium concentrations, leading to an underestimation of sodium concentrations.

### Human Subject Studies

### T₂* Values in Whole Brain Across Study Subjects

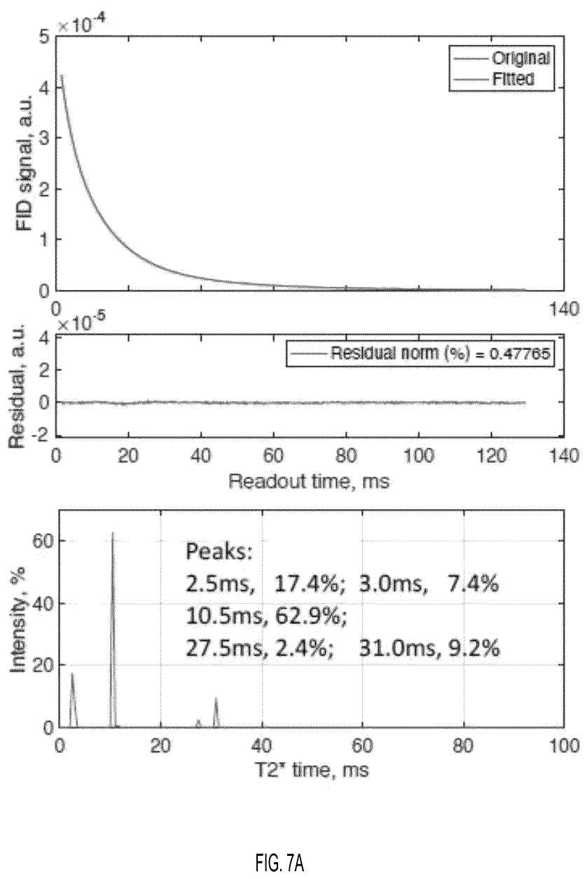

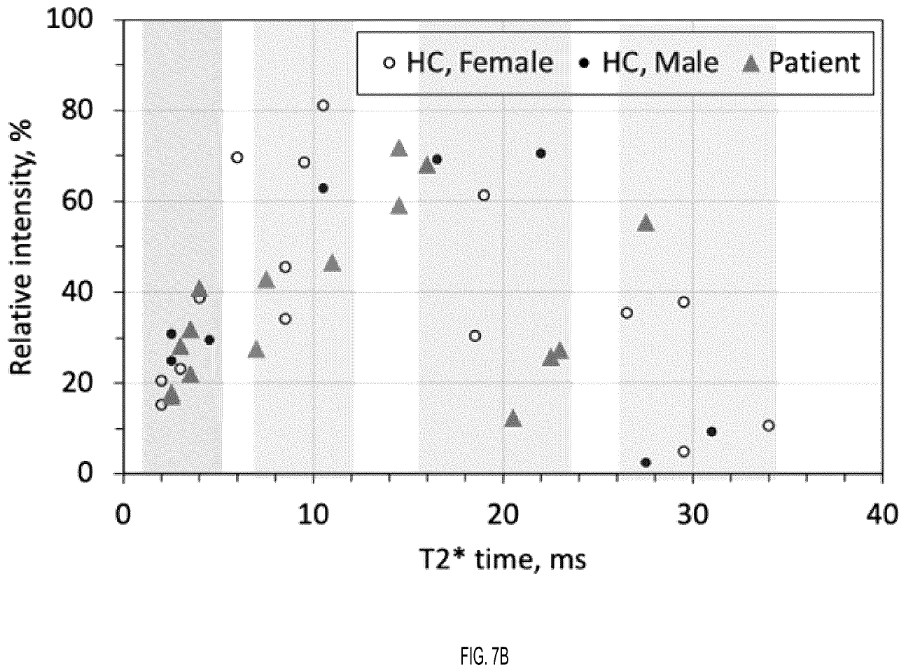

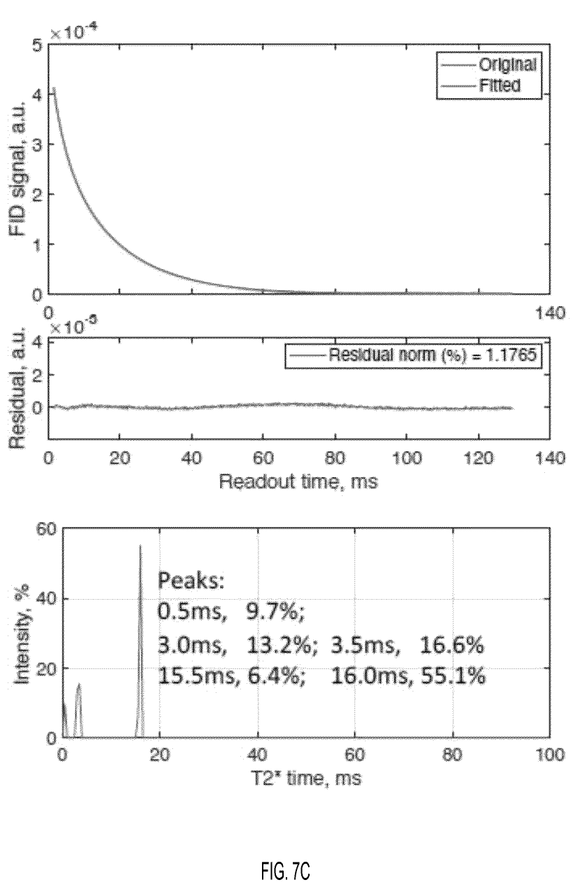

FIGS. 7A-7C present a scattering plot of individual T₂* components from the T₂* spectra across all the subjects studied. Typical T₂* spectra and associated FID signals from whole brain of the subjects are shown in FIG. 7A for a healthy young subject (21 years old, male) and FIG. 7C for an epilepsy patient (31 years old, male). FIG. 7B is the scattering (e.g., scatter) plot of individual T₂* components in the subject brains. The peaks in the T₂* spectra can be sparse (e.g., just 2-4 peaks), suggesting that a global set of T₂* values (T_{2,mo}*, T_{2,bs}*, T_{2,bl}*) can be a plausible estimate for the whole brain (FIG. 7A, 7C). However, these T₂* values are slightly different from subject to subject (FIG. 7B). The short-T₂* component can be clearly crowded in the range of 1-5 ms, while the long-T₂* is widely scattered in the three bands centered at 10, 20, and 30 ms, respectively. The long-T₂* component can be shifted to lower values in the patient group, compared with the healthy group, while there can be no difference between male and female subjects in the healthy group (statistical significance may be unclear due to the small sample size). Therefore, the T₂* values can be heterogeneous across the subjects.

### Mono-T₂ and Bi-T₂ Sodium Separation

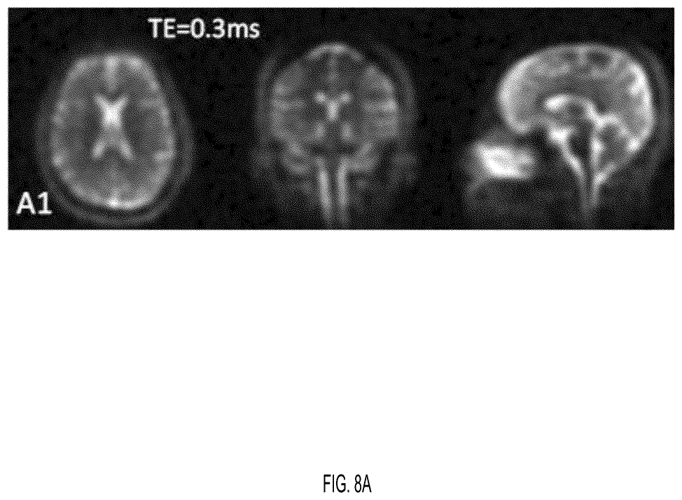

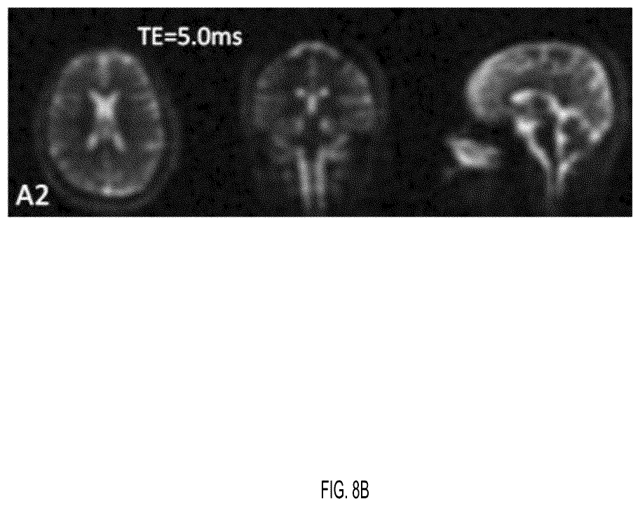

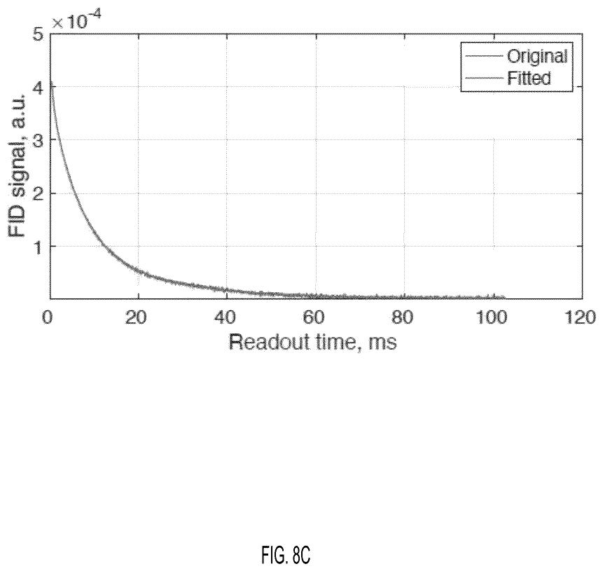

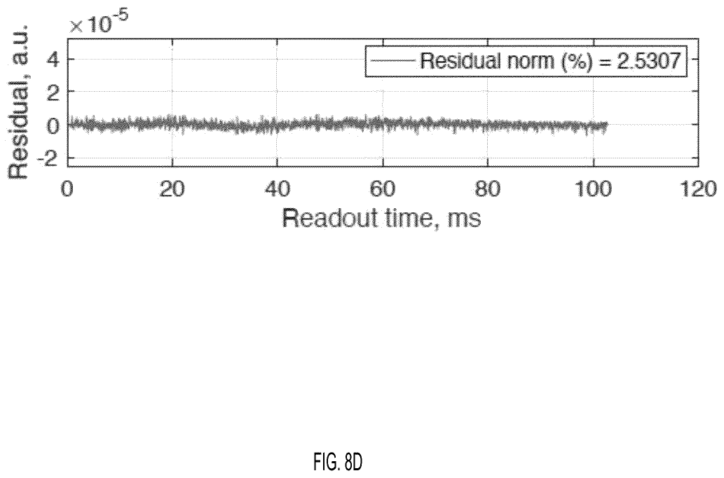

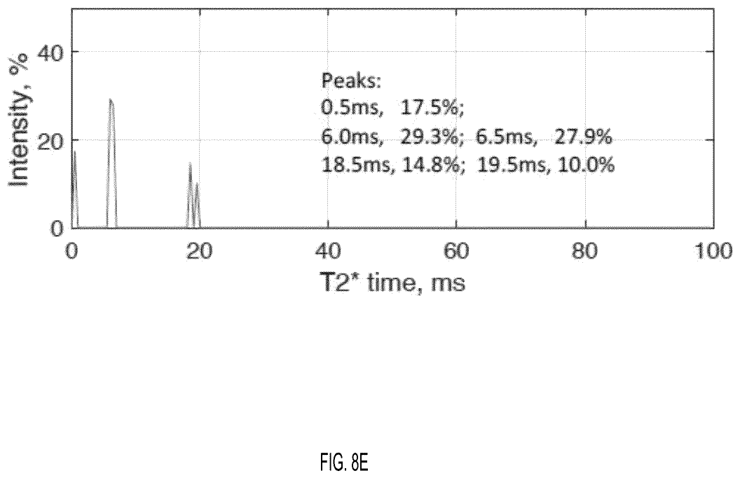

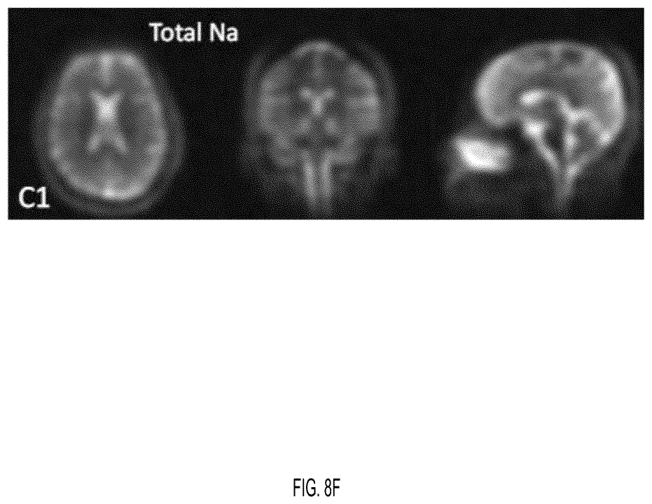

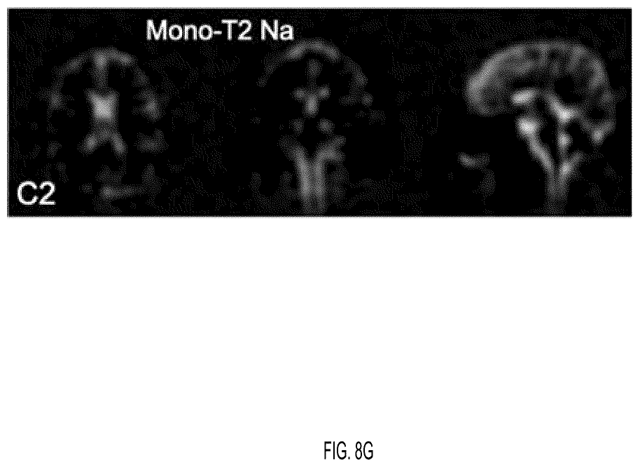

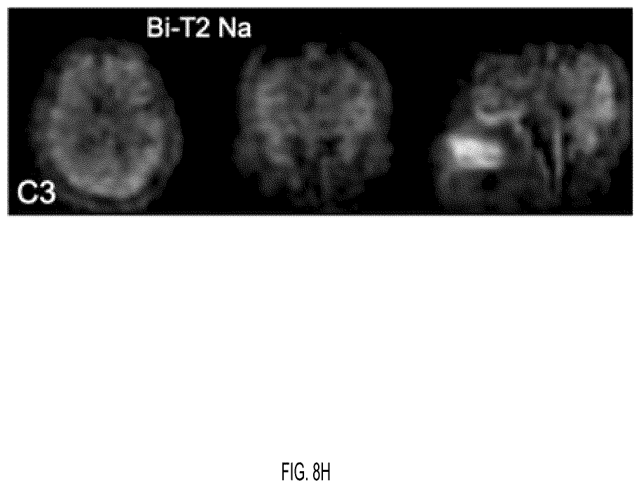

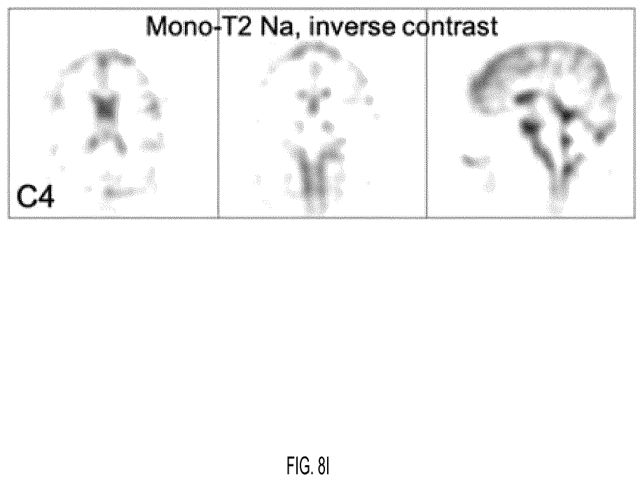

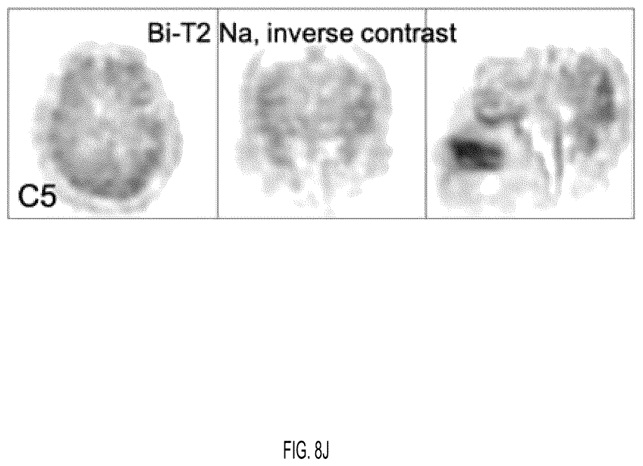

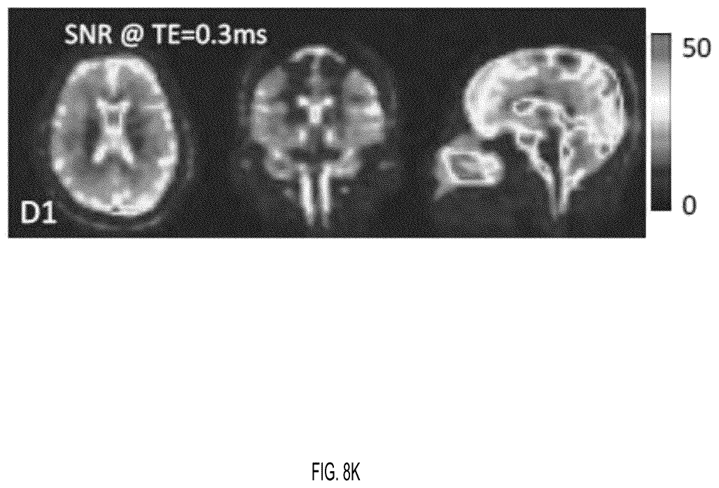

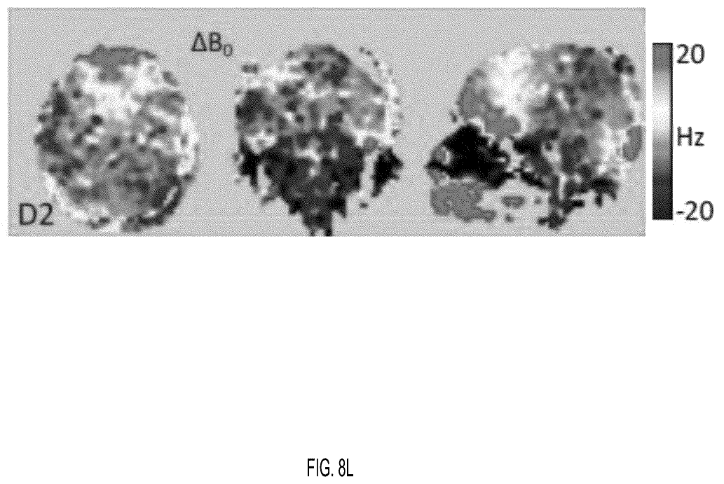

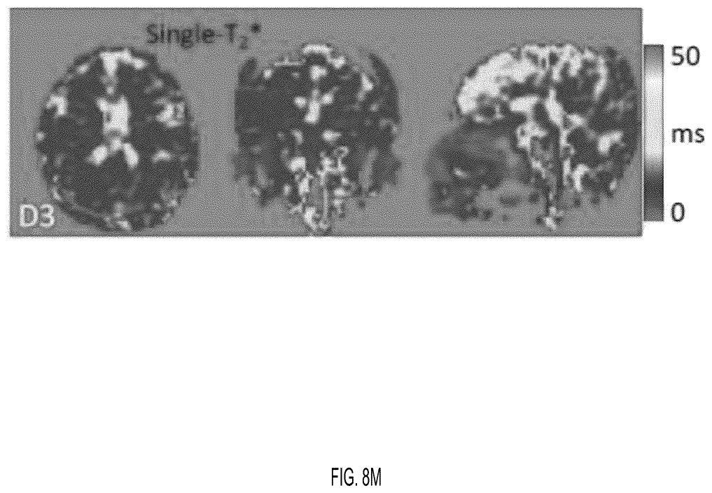

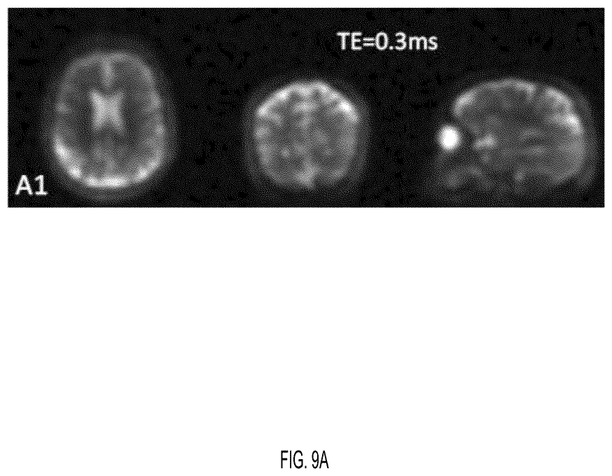

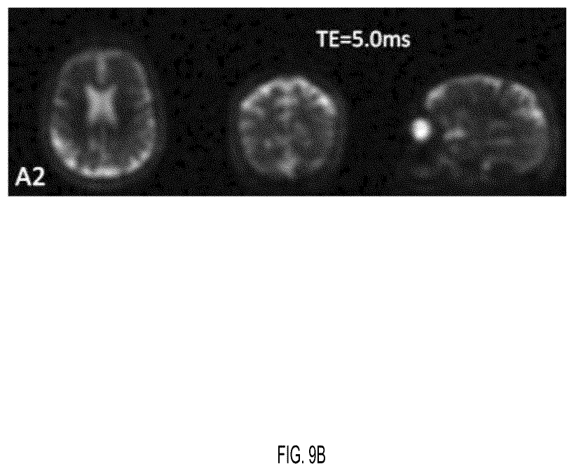

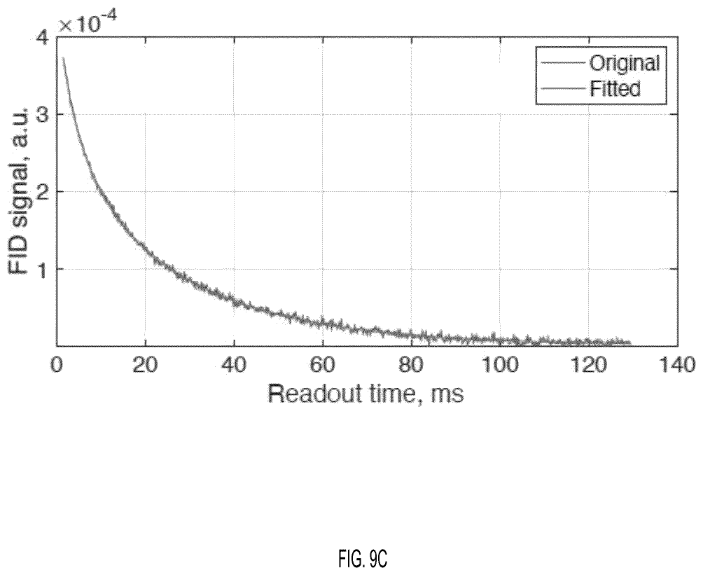

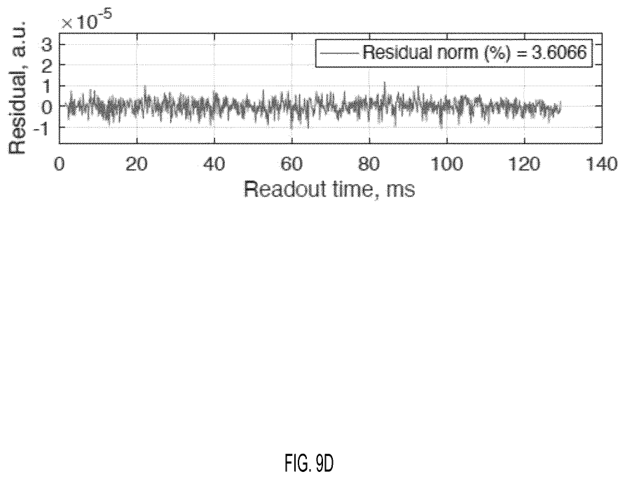

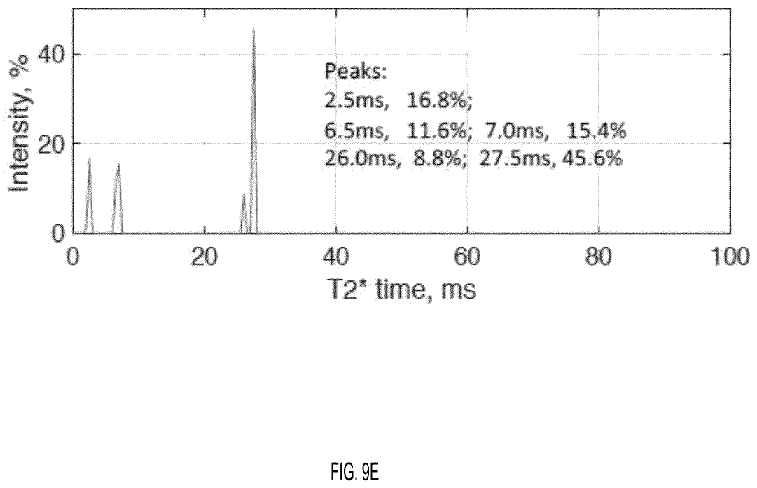

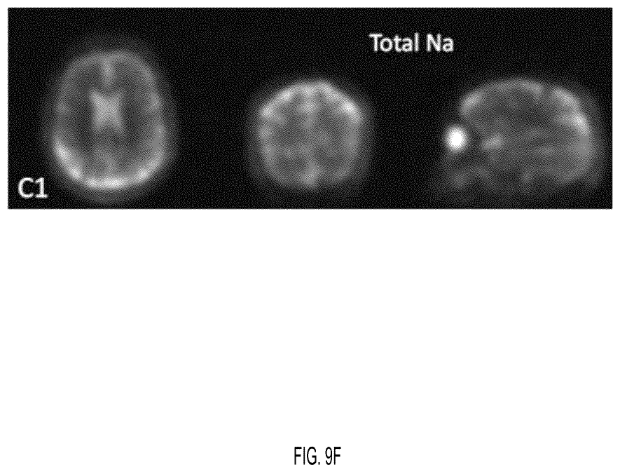

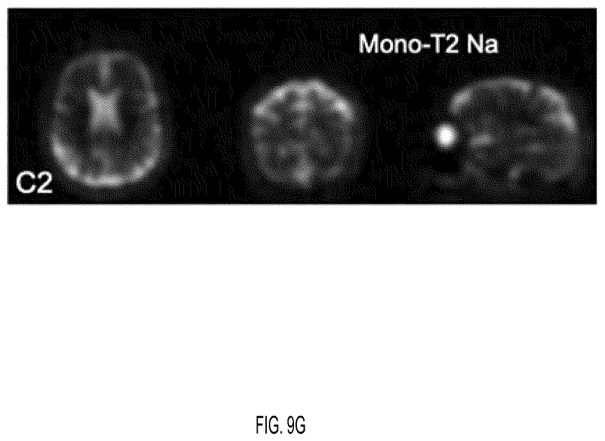

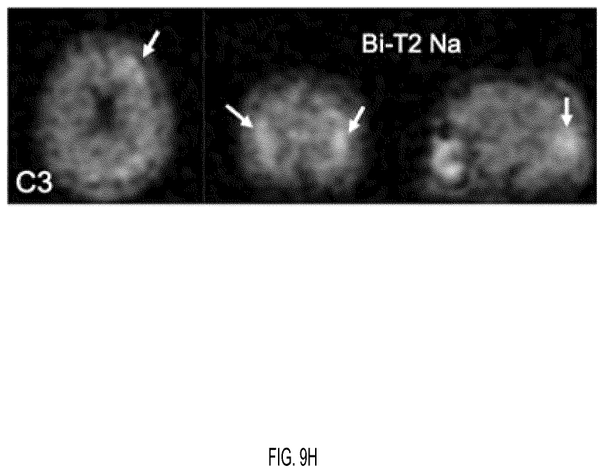

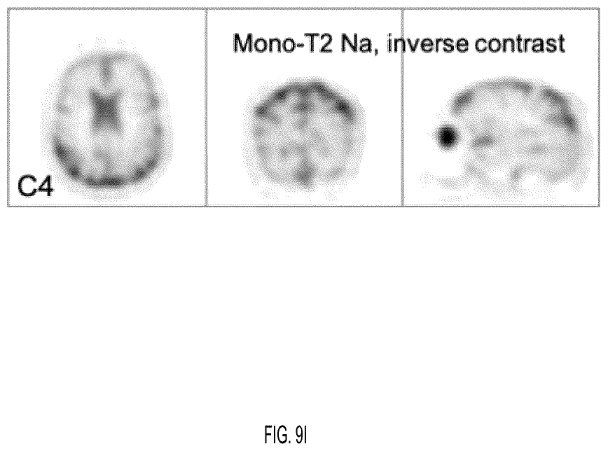

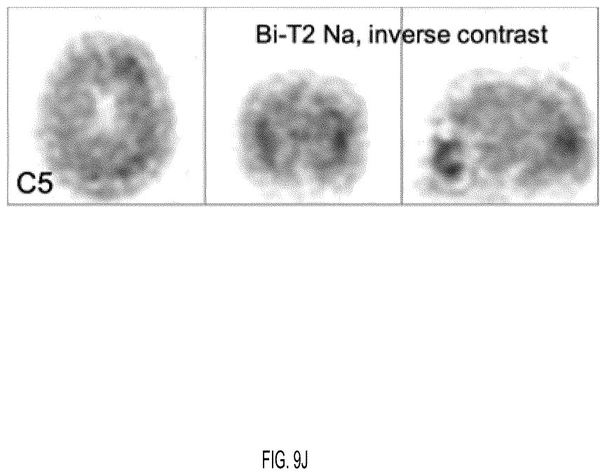

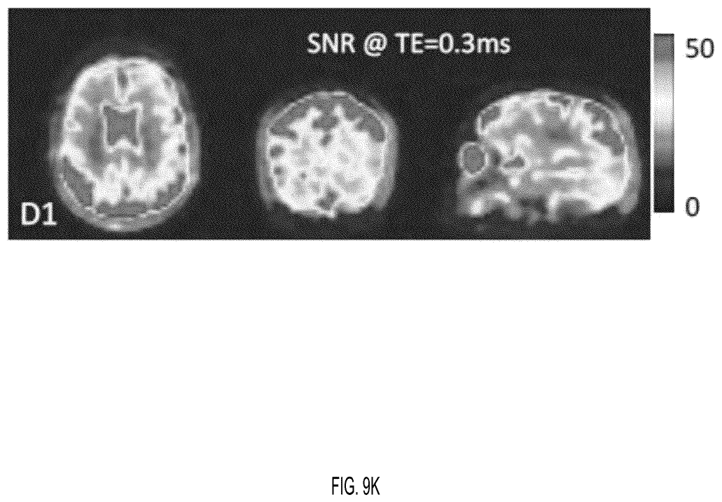

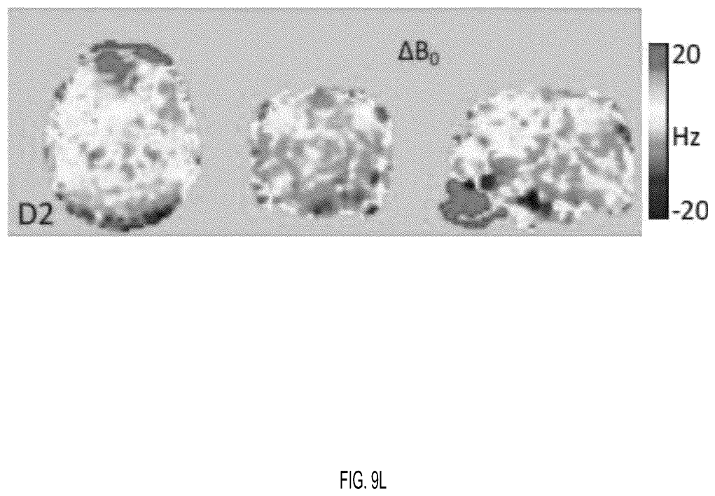

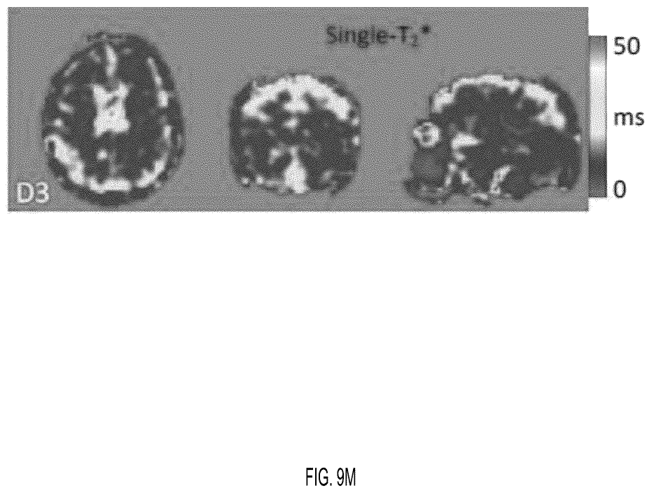

FIGS. 8A-8M and FIGS. 9A-9M present two typical cases of the human studies in full implementation of the mono-T₂ and bi-T₂ sodium separation. Case 1 (FIGS. 8A-8J) is from a 26-year-old healthy female, and includes 3D sodium images of the brain at TE₁/TE₂=0.3/5 ms (FIGS. 8A and 8B), FID signal of whole brain and associated fitting error and T₂* spectrum (FIGS. 8C-8E), the separated sodium images from the two-TE images using (T_{2,mo}*, T_{2,bs}*, T_{2,bl}*)=(50.0, 6.0, 19.0) ms (FIGS. 8F-8H), and inverse-contrast displays (FIGS. 8I and 8J). In FIGS. 8K-8M are SNR, ΔB₀, and single-T₂* maps calculated from the two-TE images in FIGS. 8A and 8B. Case 2 (FIGS. 9A-9M) is from a 59-year-old male patient with bipolar disorder. The separated sodium images were attained at (T_{2,mo}*, T_{2,bs}*, T_{2,bl}*)=(50.0, 2.5, 7.0) ms according to the peaks in FIG. 9E.

FIGS. 8A-8M indicate that signals from CSF in the brain were effectively separated into the mono-T₂ sodium image (FIGS. 8G or 8I), while signals from brain tissues such as gray and white matters were separated into the bi-T₂ sodium image (FIGS. 8H or 8J). Signal intensity across brain tissues can look more uniform in the bi-T₂ sodium images than in the mono-T₂ sodium images (FIG. 8G), total sodium images (FIG. 8F), and TE1-images (FIG. 8A). SNR in FIG. 8K can be 25 and higher in most regions of the brain, assuring a robust separation as suggested in the simulations in FIGS. 5A-5F. The field inhomogeneity ΔB₀ in FIG. 8L varied between ±20 Hz across the brain, with the largest off-resonance in the prefrontal and occipital lobes, leading to visible blurring of the tissues in the bi-T₂ sodium images (FIGS. 8H or 8J, sagittal). The single-T₂* map in FIG. 8M provides a spatial distribution of short and long T₂* components across the brain, complementary to T₂* spectrum in FIG. 8E. It also indicates that majority of long T₂* components are located in the prefrontal lobe in this particular case (FIG. 8M, sagittal).

FIGS. 8A-8M illustrate the results of human study #1 (26-year-old female, healthy). FIGS. 8A and 8B show 3D sodium images of the brain in three orthogonal slices at TE1/TE2=0.3/5 ms. FIGS. 8C-8E show FID signal of the whole brain and associated fitting error and T₂* spectrum. FIGS. 8F-8J show separated sodium images from the two-TE images in FIGS. 8A and 8B using (T_{2,mo}*, T_{2,bs}*, T_{2,bl}*)=(50.0, 6.0, 19.0) ms according to FIG. 8E. FIGS. 8I and 8J are inverse-contrast display of FIGS. 8G and 8H to highlight low intensity. All of the images in FIGS. 8A, 8B and 8F-8J were displayed in the same window/level. FIGS. 8K-8M show maps of SNR, ΔB₀, and single-T₂*, calculated from the 2-TE images in FIGS. 8A and 8B.

FIGS. 9A-9M demonstrate potential benefits from the bi-T₂ sodium images of patients with neurological disorders such as bipolar disorder which is known to cause abnormally-high intracellular sodium concentration in the brain but locations are unknown. The bi-T₂ sodium images (FIGS. 9H or 9J) clearly highlighted brain regions of an elevated bi-T₂ sodium signal against surrounding tissues, with a ratio of 1.78 vs. 1.40 (or 27.1% increase) before the separation (FIG. 9F). These regions have no visible contrast in the total or TE₁-images (FIGS. 9A or 9F). SNR in these regions is 40 and higher (FIG. 9K), supporting a robust separation. The field inhomogeneity ΔB₀ in these regions is low (<5 Hz, FIG. 9L), excluding field-induced artifacts. The single-T₂* map in FIG. 9M shows abnormally low T₂* values in these regions, confirming an increase in short-T₂* components.

FIGS. 9A-9M illustrate the results of human study #2 (59-year-old male, bipolar disorder patient). FIGS. 9A and 9B show 3D sodium images of the brain at TE₁/TE₂=0.3/5 ms. FIGS. 9C-9E show FID signal of the whole brain and associated fitting error and T₂* spectrum. FIGS. 9F-9J show separated sodium images from the 2-TE images in FIGS. 9A and 9B using (T_{2,mo}*, T_{2,bs}*, T_{2,bl}*)=(50.0, 2.5, 7.0) ms according to peaks in FIG. 9E. FIGS. 9I and 9J are inverse-contrast display of FIGS. 9G and 9H to highlight low intensity. All the images in FIGS. FIGS. 9A, 9B and 9F-9J were displayed in the same window/level, except FIGS. 9H and 9J where W/L was halved. FIGS. 9K-9M show maps of SNR, ΔB₀, and single-T₂*, calculated from the 2-TE images in FIGS. 9A and 9B. Note that the bi-T₂ sodium images in FIG. 9H (or FIG. 9J) clearly highlighted brain regions (arrows) with an elevated bi-T₂ sodium concentration.

### Estimates of Extra- and Intracellular Volume Fractions

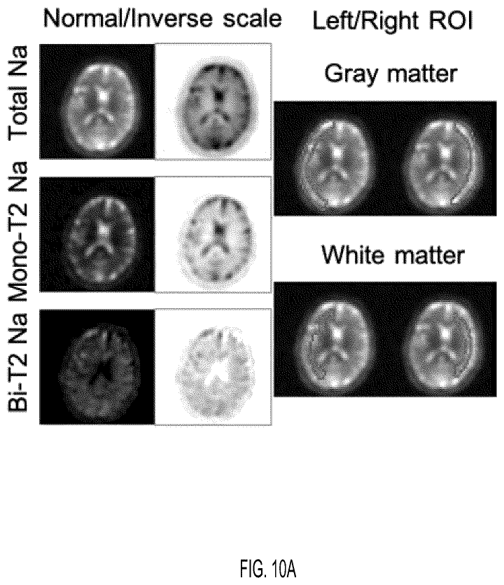

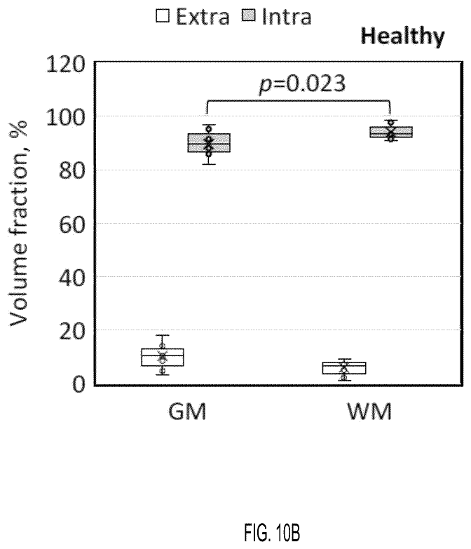

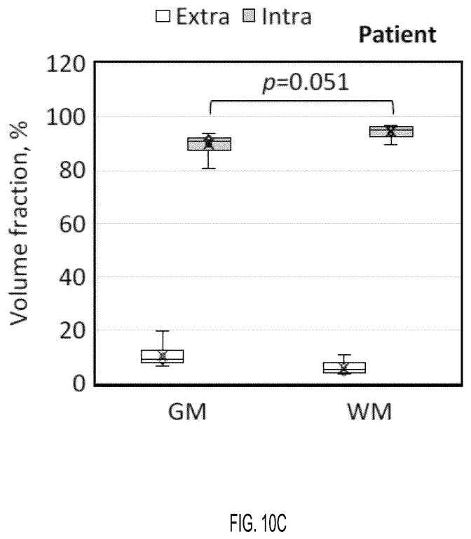

In the healthy group (FIGS. 10A-10C), the difference in volume fraction between the gray and white matters is significant (P=0.023): 89.6±4.5% vs. 94.0±2.6% for the intracellular space (75% vs. 92% 8), and 10.4±4.5% vs. 6.0±2.6% for the extracellular space. No significant difference (P=0.953) was found between the healthy and patient groups due to small samples (n=9 and 6). FIGS. 10A-10C illustrate the upper-limit volume fraction of extra- and intracellular spaces by assigning all the mono-T₂ sodium into extracellular space at Cₑₓ=145 mM and all the bi-T₂ sodium into intracellular space at Cᵢₙ=15 mM. FIG. 10A illustrates typical sodium images (total, mono-T₂, and bi-T₂) and regions of interest (ROIs) for the gray matter (GM) and white matter (WM) in a slice of a healthy subject. FIG. 10B illustrates volume fractions for the healthy group (n=9). FIG. 10C illustrates volume fractions for the patient group (n=6). The difference in volume fraction is statistically significant between the gray and white matters (P=0.023) for the healthy group, but not for the patient group (P=0.051). It is not significant between the healthy and patient groups for the gray or white matter (P=0.953).

The MSQ technique of the present disclosure can be demonstrated using computer simulations, physical phantoms, and human subjects, to be able to separate mono-T₂ and bi-T₂ sodium signals voxel-wise. The physics behind the technique can be based on the intrinsic difference in T₂ relaxation between sodium nuclear spins: mono-vs. bi-exponential decay. In the restriction of total scan time, the two-TE scheme, instead of the eight-TEs, was selected for smaller transfer of random noise during the separation (FIGS. 4A-4E). The measurement of T₂* spectrum from FID signals of entire brain and the application of a global set of T₂* values (T_{2,mo}*, T_{2,bs}*, T_{2,bl}*) were tested feasible to humans. In case of not plausible for a global set of T₂* values (i.e., T₂* spatially varying substantially), multi-regional sets, or a linear combination of them, may be used.

The data presented herein have demonstrated the feasibility of a multi-TE single-quantum sodium MRI technique to separate mono-T₂ and bi-T₂ sodium signals in a fashion of voxel by voxel. The MSQ technique can be based on solid physics related to the intrinsic difference in T₂ relaxation between the two populations of sodium nuclear spins. The two-TE sampling scheme stands out for smaller noise transfer during the separation. A global set of T₂* values (T_{2,mo}*, T_{2,bs}*, T_{2,bl}*) measured on T₂* spectrum of whole brain was tested applicable to humans.

### Extrapolation of N-Term Exponential Decay

An algorithm for exponential extrapolation can be used for the recovery of FID signals. If a signal f(t) is an N-term exponential decay as defined in Eq. 11a with parameters {Aᵢ, bᵢ; i=1,2, . . . , N}, and is sampled at a uniform interval Δt, then a sample f(t₀) at time t₀ can be represented by a linear combination of its late-time neighboring samples {f(t₀+jΔt), j=1,2, . . . , M}, as shown in Eq. 11b, with coefficients {aⱼ, j=1,2, . . . , M≥N} to be determined.

$$f ( t ) = {\sum }_{i = 1}^{N} {A}_{i} {e}^{- t \cdot {b}_{i}} \qquad Eq . 11 a$$

$$f ( {t}_{0} ) = {\sum }_{j = 1}^{M} {a}_{j} f ( {t}_{0} + j Δ t ) \qquad Eq . 11 b$$

Proof. Extending f(t₀+jΔt) in Eq. 11b according to Eq. 11a gives:

$$f ( {t}_{0} ) = {\sum }_{j = 1}^{M} {a}_{j} [ {\sum }_{i = 1}^{N} ( {A}_{i} {e}^{- {t}_{0} \cdot {b}_{i}} ) ( {e}^{- j Δ t \cdot {b}_{i}} ) ] = {\sum }_{i = 1}^{N} {A}_{i} {e}^{- {t}_{0} \cdot {b}_{i}} ( {\sum }_{j = 1}^{M} {a}_{j} {e}^{- j Δ t \cdot {b}_{i}} ) \qquad Eq . 11 c$$

Select time-invariant coefficients {aⱼ, j=1,2, . . . , M>N} to satisfy Eq. 11d, thus Eq. 11b holds.

$${\sum }_{j = 1}^{M} {a}_{j} {e}^{- j Δ t \cdot {b}_{i}} = 1 , for i = 1 , 2 , … N \qquad Eq . 11 d$$

The descriptions above can be for backward extrapolation in time and can be used in the recovery of FID signal. The forward extrapolation can also hold if Δt is replaced with −Δt in Eqs. 11b-11d. To find the unknown coefficients {aⱼ, j=1,2, . . . , M}, Eq. 11b, instead of Eq. 11d, can usually be used on such a segment of f(t) that it is not distorted and involves all the N exponential decays. The number of data samples on the segment can be larger than M to form an over-determined problem in case of random noise existing in the signal f(t).

The multiple TE acquisitions can simultaneously quantify the concentrations, C, of bi-T₂ sodium, mono-T₂ sodium, and total sodium through an integrated calibration.

$${C}_{bi} = {C}_{calib} \cdot ( {I}_{bi} - {I}_{noise , bi} ) / ( {I}_{calib , total} / {η}_{calib} - {I}_{noise , bi} ) \qquad Eq . 12 a$$

$${C}_{mo} = {C}_{calib} \cdot ( {I}_{mo} - {I}_{noise , mo} ) / ( {I}_{calib , total} / {η}_{calib} - {I}_{noise , mo} ) \qquad Eq . 12 b$$

$${C}_{total} = {C}_{calib} \cdot ( {I}_{total} - {I}_{noise , total} ) / ( {I}_{calib , total} / {η}_{calib} - {I}_{noise , total} ) \qquad Eq . 12 c$$

C_{calib} is the sodium concentration of a compartment for calibration, such as cerebrospinal fluid (CSF) for internal calibration or saline water for external calibration. Iₙₒᵢₛₑ is image intensity in a noise-only region on the sodium images. C_{calib,total} is signal intensity in a region of the calibration compartment on the total sodium image. η_{calib} is saturation factor of T₁ relaxation in the calibration compartment at a repetition time of TR, η_{calib}=1−exp(−TR/T₁). This factor can be close to 1.0 when TR≥100 ms.

### The Calculation Stability of T₂* Spectrum at a High Resolution of ΔT₂*=0.5 ms

T₂* spectrum was calculated via Eq. 4 on an FID signal using an established algorithm called non-negative least squares (NNLS) at a high spectral resolution of ΔT₂*=0.5 ms in a range of 0.5-100 ms. This high resolution can raise a concern of the stability of the calculation as the base functions at these spectral locations, exp(−t/T₂*) are not independent. To address this concern, the singular value decomposition (SVD) can be employed to analyze the transfer matrix E, and numerical simulations can be used to detail the impact of random noise on the T₂* spectrum.

### VSD Analysis on the Transfer Matrix E

$${E}_{i , j} ≡ exp ( - {t}_{i} / {T}_{2 , j}^{*} ) , i = 1 , 2 , … , N , j = 1 , 2 , … , M , N >> M \qquad Eq . 13 a$$

$${E}^{T} E = U \sum {V}^{T} \qquad Eq . 13 b$$

$$\sum = diag ( {σ}_{1} , {σ}_{2} , … , {σ}_{M} ) \qquad Eq . 13 c$$

The sampling time tᵢ=TE+(i−1)*Δt and spectral point T_{2,j}*=j*ΔT_{2,q}*. Singular values {σⱼ, j=1,2, . . . , M} determine stability of the calculation for T₂* spectrum in terms of noise interference in Eq. 4. Correlation coefficients between the base functions are also calculated.

$${R}_{j 1 , j 2} = {( {E}^{T} E )}_{j 1 , j 2} / \sqrt{{( {E}^{T} E )}_{j 1 , j 1} {( {E}^{T} E )}_{j 2 , j 2}} , j 1 , j 2 - 1 , 2 , … , M \qquad Eq . 14$$

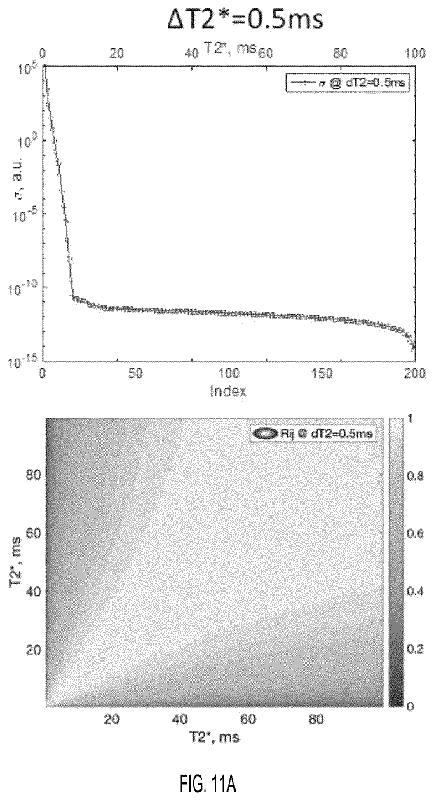

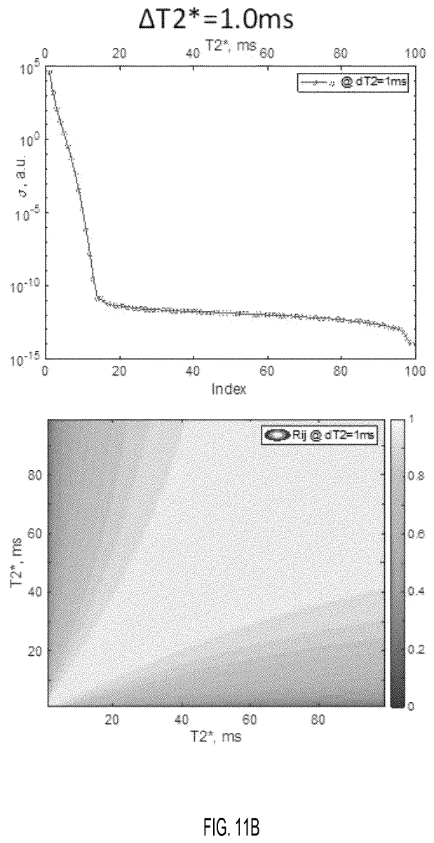

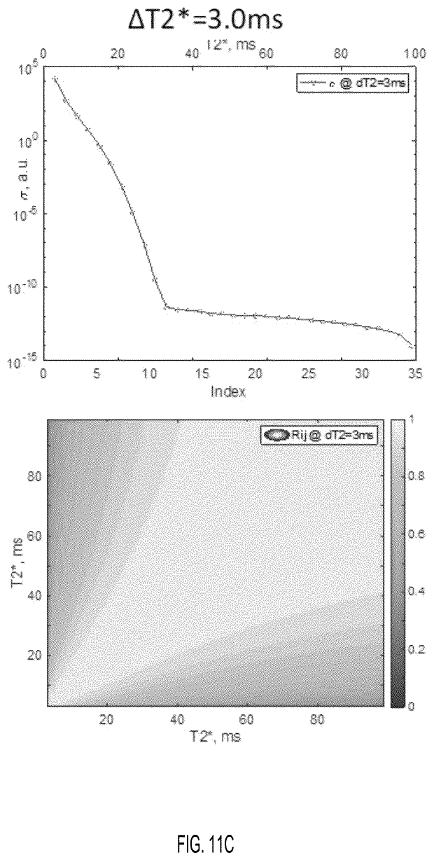

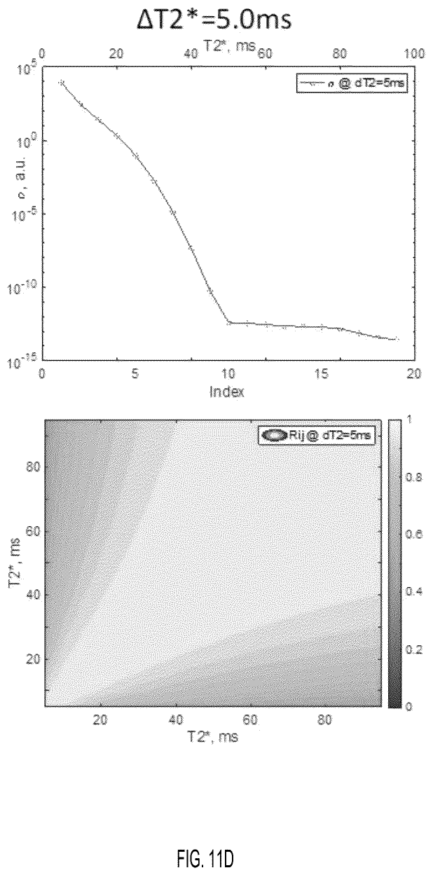

At Δt=0.05 ms, TE=0.2 ms and N=2048, the singular values and correlation coefficients were calculated and illustrated in FIGS. 11A-11D. The singular value σ quickly decreases to zero (<10⁻¹⁰) at index (15, 13, 10, 9) when ΔT₂* increases from 0.5 ms to 1.0, 3.0 and 5.0 ms, respectively. This indicates the existence of null subspace or multiple solutions for T₂* spectrum (FIG. 11A, top). The normalized correlation coefficients R between any two T₂* base functions is spreading away from diagonal line, confirming non-orthogonal between the base functions (FIG. 11A, bottom). However, the extent of spreading is narrower for short T₂* values at high resolution ΔT₂*=0.5 ms than at low resolution ΔT₂*=5 ms.

FIGS. 11A-11D illustrate the calculation stability of T₂* spectra using SVD analysis on matrix E^{T}E (top) and the base-correlation on matrix E (bottom). FIGS. 11A-11D illustrate T₂* spectral resolution at ΔT₂*=0.5, 1.0, 3.0, and 5.0 ms. In the top, singular value o quickly decreases to zero (<10⁻¹⁰) at index (15, 13, 10, 9) respectively, indicating the existence of null subspace or multiple solutions for the T₂* spectrum. In the bottom, the normalized correlation coefficient R_{j1,j2} between any two T₂* base functions exp(−t/T_{2,j}*) is spreading away from diagonal line, showing non-orthogonal between the base functions.

### Numerical Simulation for the Impact of Random Noise on the T₂* Spectrum

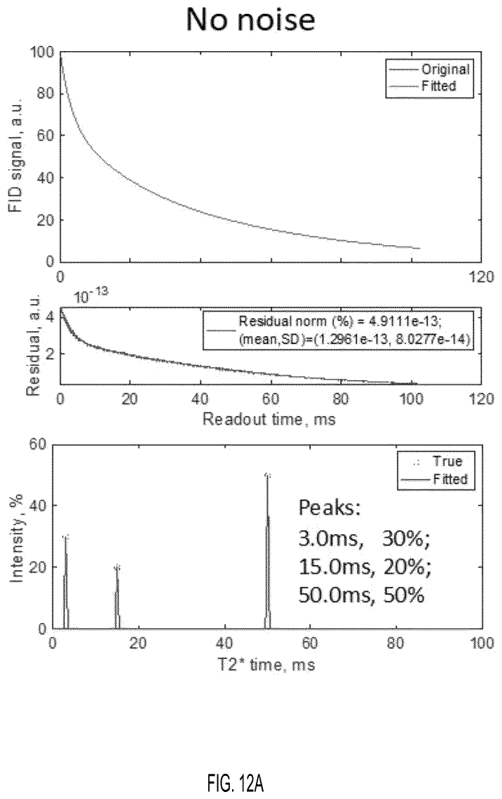

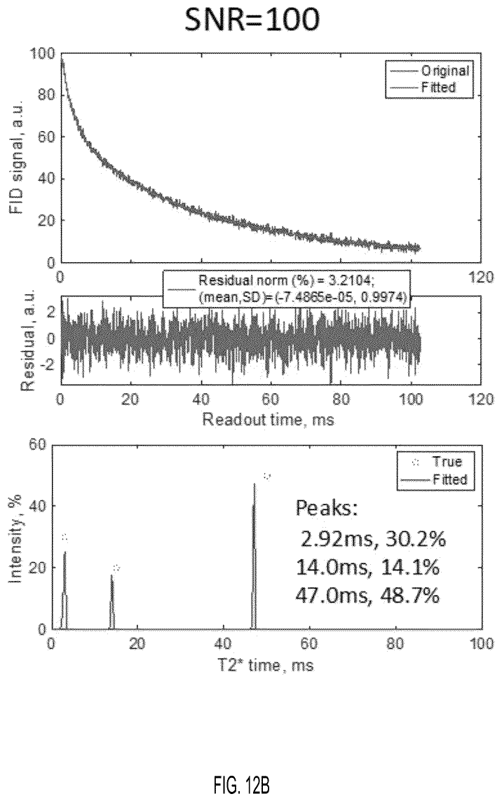

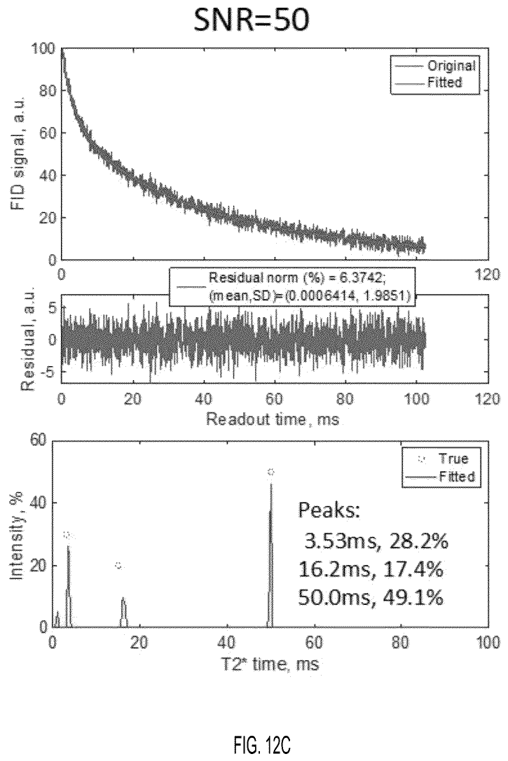

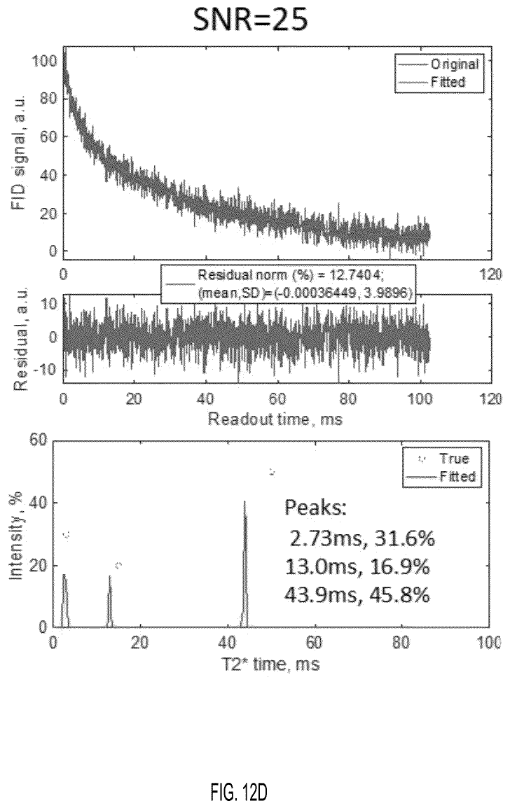

The simulation can be performed at three components, T₂*=(3, 15, 50) ms with relative amplitudes A=(30, 20, 50), with an additive normal random noise generated by function randn(n, 1), at SNR=100, 50, and 25. Outcomes of the simulation can be summarized in FIGS. 12A-12D, where the peak parameters at doublets (FIGS. 12A-12D, bottom) were linearly combined with amplitude-weighting by the left- and right-peaklets (Eqs. 15a and 15b).

$${T}_{2}^{*} = ( {A}_{L} * {T}_{2 , L}^{*} + {A}_{R} * {T}_{2 , R}^{*} ) / A \qquad Eq . 15 a$$

$$A = {A}_{L} + {A}_{R} \qquad Eq . 15 b$$

The best spectrum can be achieved at SNR=100 among the three noisy cases, relative to no-noise. FIGS. 12A-12D illustrate the calculation stability of T₂* spectra using the algorithm NNLS via MATLAB function lsqnonneg(C,d) and the numerical simulations at three popular components: T₂*=(3, 15, 50) ms with relative amplitudes A=(30, 20, 50) and an additive random noise generated by function randn(n,1). FIGS. 12A-12D are the simulations at ΔT₂*=0.5 ms with noise at three SNR values (SNR=100, 50, and 25). The peak parameters at doublets (bottom) were linearly combined with amplitude-weighting (Eq. 15b).

### The Measurement Stability of FID Signals on Whole Brain: B₀ Shimming

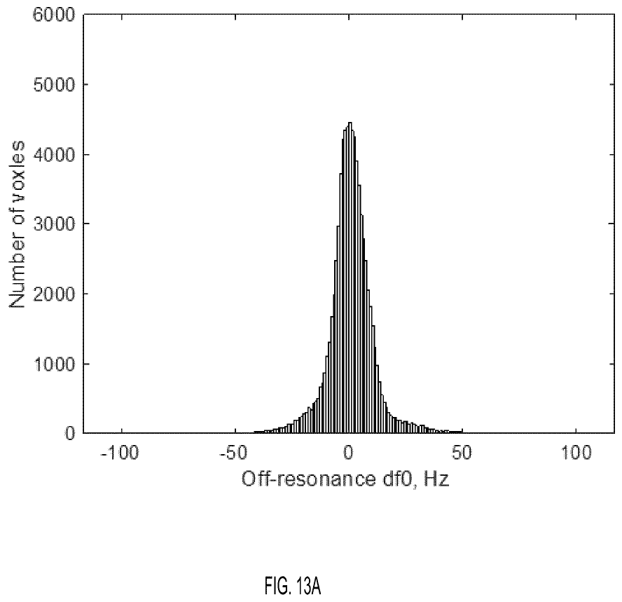

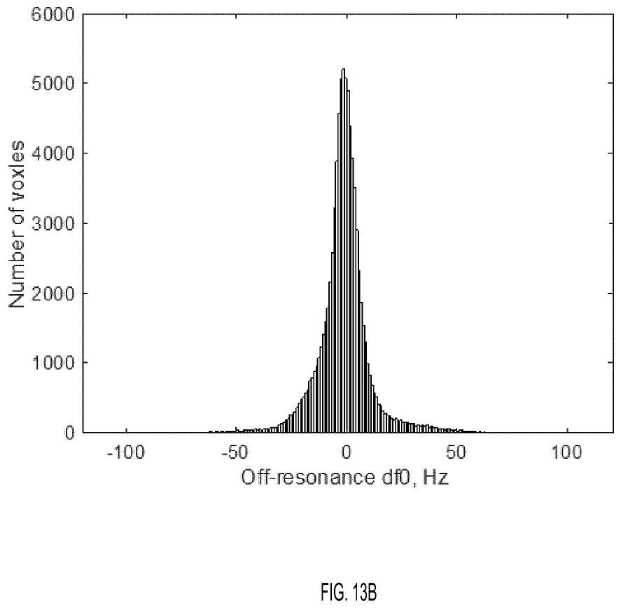

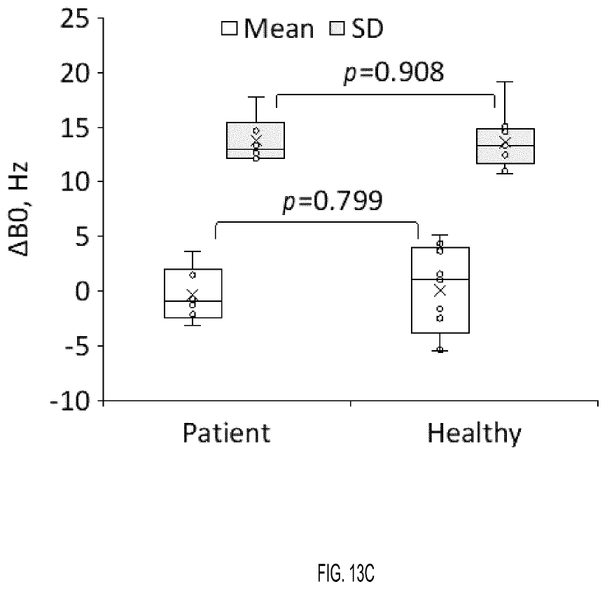

The B₀ shimming may change from subject to subject, leading to a concern on the measurement stability of FID signals, thus the T₂* spectra, from whole brain. This concern can be addressed because 1) sodium (²³Na) MRI has a 4-times lower resonance frequency than proton (1H) MRI (e.g., 33.8 vs. 127.7 MHz at 3T), and 2) a manual shimming (three iterations) is better than auto shimming. FIGS. 13A-13C presents results of all the 15 subjects studied, with a small standard deviation (SD) in whole-brain histograms. There was no significant difference between the healthy and patient groups (P=0.908). Thus, the manual shimming, or ΔB₀, is stable.

FIGS. 13A-13C illustrate whole-brain histograms of ΔB₀ mapping at TE₁/TE₂=0.5/5 ms under a manual shimming procedure. FIG. 13A illustrates a representative histogram from a healthy subject (52 years old, male), with mean±SD=1.0±10.7 Hz. FIG. 13B illustrates a representative histogram from an epilepsy patient (31 years old, male), with mean±SD=−1.2±12.1 Hz. FIG. 13C illustrates mean and SD distribution of whole-brain ΔB₀ histograms from all the 9 healthy and 6 patients studied, showing no significant difference between the two groups (healthy vs. patient), P=0.799 for the mean and P=0.908 for the SD.

### The Invisibility of CSF T₂* Peak in the Spectrum: Single T₂* Mapping

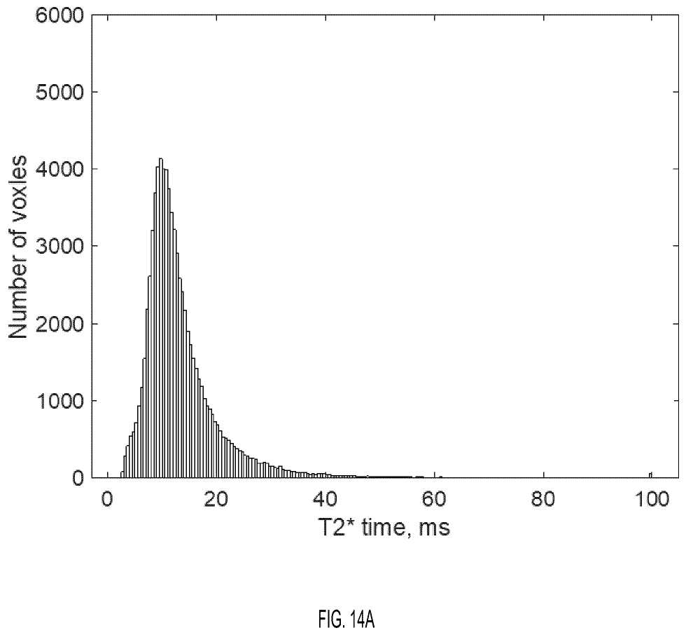

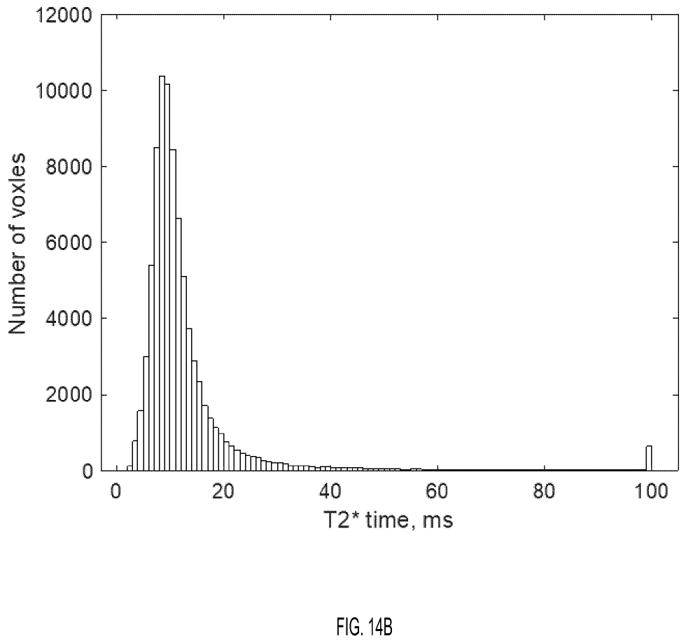

CSF in the brain can have a T₂* value of ˜50 ms as seen in single-T₂* maps (FIGS. 8A-8M and FIGS. 9A-9M). But this sodium population may not be observed in the T₂* spectra. This phenomenon might be caused by small volume of CSF relative to whole brain. To confirm this cause, FIGS. 14A-14B present two representative whole-brain histograms of single-T₂* mapping, with very small numbers of voxels (invisible bins) for CSF at T₂*˜50 ms.

FIGS. 14A-14B illustrate representative whole-brain histograms of single-T₂* mapping at TE₁/TE₂=0.5/5 ms. FIG. 14A illustrates a healthy subject (52 years old, male). FIG. 14B illustrates an epilepsy patient (31 years old, male). These, as well as the other healthy subjects and patients studied, showed very small numbers (invisible bins) of voxels for CSF at T₂*˜50 ms. A visible bin at T₂*=100 ms counts voxels of T₂* values ≥100 ms.

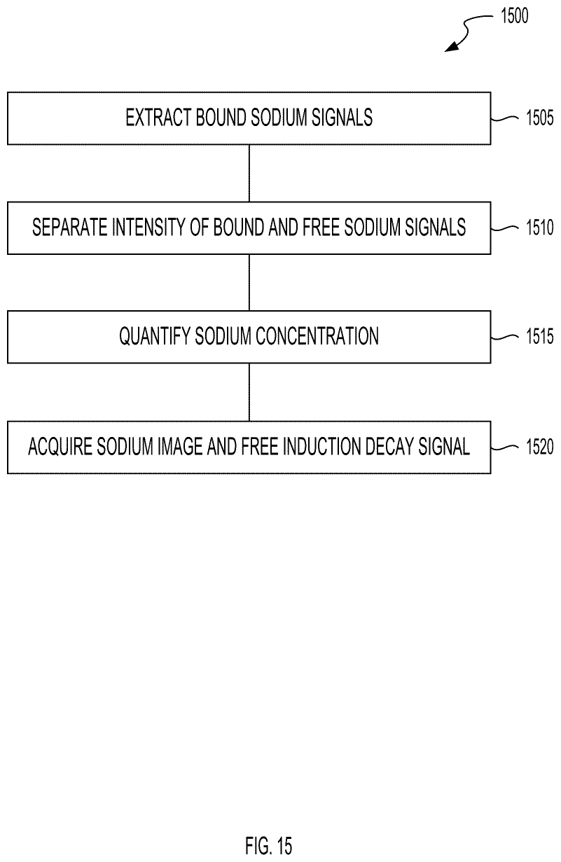

FIG. 15 illustrates a method 1500 of quantifying sodium concentration (e.g., MSQ technique). The method 1500 can include a method for multi-TE single-quantum sodium (²³Na) MRI. The method 1500 can include a clinically translatable technique for separation of mono-T₂ and bi-T₂ sodium signals. The method 1500 can include extracting bi-T₂ sodium signals (BLOCK 1505). The method 1500 can include separating the intensity of bi-T₂ and mono-T₂ sodium signals (BLOCK 1510). The method 1500 can include quantifying sodium concentration (BLOCK 1515). The method 1500 can include acquiring a sodium image and the mono-T₂ induction decay signal (BLOCK 1520).

The method 1500 can include extracting bi-T₂ sodium signals (BLOCK 1505). For example, the method 1500 can include extracting one or more bi-T₂ sodium signals from one or more echo time acquisitions. The one or more echo time acquisitions can be performed with single-quantum sodium excitations. The method 1500 can include calculating or measuring one or more bi-T₂ sodium signals.

The method 1500 can include separating the intensity of bi-T₂ and mono-T₂ sodium signals (BLOCK 1510). For example, the method 1500 can include separating an intensity of the one or more bi-T₂ sodium signals from an intensity of one or more mono-T₂ sodium signals. The method 1500 can include separating, via a matrix equation comprising at least one of T₂ decays or T₂* decays of mono-T₂ sodium and bi-T₂ sodium, an intensity of the one or more bi-T₂ sodium signals from an intensity of one or more mono-T₂ sodium signals. The one or more echo time acquisitions can simultaneously quantify bi-T₂ sodium concentration, mono-T₂ sodium concentration, and total sodium concentration. For example, the multiple TE acquisitions can simultaneously quantify the concentrations of bi-T₂ sodium, mono-T₂ sodium, and total sodium through an integrated calibration based on Eqs. 12A-12C. The matrix equation can eliminate contamination between the one or more bi-T₂ sodium signals and the one or more mono-T₂ sodium signals. The method 1500 can include using alternative ways to eliminate the contamination between the mono-T₂ and bi-T₂ sodium signals, such as artificial neural network (ANN) and artificial intelligence (AI), rather than using the matrix equation. The method 1500 can include using non-negative least squares (NNLS) to solve the matrix equation. The method 1500 can include using alternative algorithms to solve the matrix equation, rather than using the NNLS.

The method 1500 can include differentiating the mono-T₂ sodium with short-T₂ relaxation from the bi-T₂ sodium. For example, the method 1500 can include distinguishing the mono-T₂ sodium from the bi-T₂ sodium. The method 1500 can include differentiating the mono-T₂ sodium with T₂* relaxation from the bi-T₂ sodium.

The method 1500 can include quantifying sodium concentration (BLOCK 1515). For example, the sodium concentration can include the bi-T₂ sodium concentration. The sodium concentration can include the mono-T₂ sodium concentration. The sodium concentration can include the total sodium concentration. The method 1500 can include quantifying the bi-T₂ sodium concentration, mono-T₂ sodium concentration, and total sodium concentration based on the one or more echo time acquisitions. The one or more echo time acquisitions can simultaneously quantify the bi-T₂ sodium concentration, mono-T₂ sodium concentration, and total sodium concentration. The one or more echo time acquisitions can provide the quantification of the bi-T₂ sodium concentration, mono-T₂ sodium concentration, and total sodium concentration. The data acquired from the extraction of the one or more bi-T₂ sodium signals can be processed to quantify the bi-T₂ sodium concentration, mono-T₂ sodium concentration, and total sodium concentration. For example, an integrated calibration can allow for the one or more echo time acquisitions to simultaneously quantify the bi-T₂ sodium concentration, mono-T₂ sodium concentration, and total sodium concentration.

The method 1500 can include acquiring the sodium image and the mono-T₂ induction decay signal (BLOCK 1520). For example, the method 1500 can include acquiring one or more echo time sodium images. The method 1500 can include using the sodium image as an input. The method 1500 can include acquiring the mono-T₂ induction decay signal from whole or part of imaging volume. The method 1500 can include using the mono-T₂ induction decay signal as an input.

The method 1500 can include converting the mono-T₂ induction decay signal into T₂* spectrum. The method 1500 can include determining a set of T₂* values (T_{2,mo}*, T_{2,bs}*, T_{2,bl}*) for the matrix equation. The method 1500 can include using a curve-fitting to the mono-T₂ induction decay signal to obtain the T₂* spectrum.

The method 1500 can include obtaining a set of T₂* values (T_{2,mo}*, T_{2,bs}*, T_{2,bl}*). The method 1500 can include obtaining a set of T₂* values (T_{2,mo}*, T_{2,bs}*, T_{2,bl}*) from alternative ways, rather than from the T₂* spectrum. The method 1500 can include using a map of T₂* values (T_{2,mo}*, T_{2,bs}*, T_{2,bl}*). The method 1500 can include using a map of T₂* values (T_{2,mo}*, T_{2,bs}*, T_{2,bl}*), rather than using a set of the T₂* values.

The method 1500 can include outputting at least one of the mono-T₂ images, bi-T₂ images, and total sodium images. The method 1500 can include differentiating the mono-T₂ sodium from the bi-T₂ sodium.

The method 1500 can include extracting bi-T₂ sodium signal from two or more echo time acquisitions. The method can include separating, via a matrix equation including at least one of T₂ (or T₂*) decays of mono-T₂ sodium and bi-T₂ sodium, an intensity of the bi-T₂ sodium signal from an intensity of mono-T₂ sodium signal. The two or more echo time acquisitions can be performed with single-quantum sodium excitations. The two or more echo time acquisitions can simultaneously quantify bi-T₂ sodium concentration, mono-T₂ sodium concentration, and total sodium concentration (e.g., the sum of mono-T₂ and bi-T₂ sodium concentrations).

A non-transitory computer-readable medium having computer-readable instructions stored thereon that, when executed by at least one controller, can cause the at least one controller to extract one or more bi-T₂ sodium signals from one or more echo time acquisitions. The at least one controller can separate, via a matrix equation comprising at least one of T₂ decays or T₂* decays of mono-T₂ sodium and bi-T₂ sodium, an intensity of the one or more bi-T₂ sodium signals from an intensity of one or more mono-T₂ sodium signals. The at least one controller can quantify bi-T₂ sodium concentration, mono-T₂ sodium concentration, and total sodium concentration based on the one or more echo time acquisitions. The one or more echo time acquisitions can be performed with single-quantum sodium excitations.

The at least one controller can acquire one or more sodium images and a mono-T₂ induction decay signal. The at least one controller can acquire the mono-T₂ induction decay signal from whole or part of imaging volume. The at least one controller can eliminate contamination between the one or more bi-T₂ sodium signals and the one or more mono-T₂ sodium signals. The at least one controller can output at least one of the mono-T₂ images, bi-T₂ images, and total sodium images.

The at least one controller can convert mono-T₂ induction decay signal into T₂* spectrum. The at least one controller can determine a set of T₂* values (T_{2,mo}*, T_{2,bs}*, T_{2,bl}*) for the matrix equation. The at least one controller can use a curve-fitting to the mono-T₂ induction decay signal to obtain the T₂* spectrum. The at least one controller can obtain a set of T₂* values (T_{2,mo}*, T_{2,bs}*, T_{2,bl}*). The at least one controller can use a map of T₂* values (T_{2,mo}*, T_{2,bs}*, T_{2,bl}*). The at least one controller can eliminate contamination between the one or more mono-T₂ sodium signals and the one or more bi-T₂ sodium signals using an artificial neural network or artificial intelligence. The at least one controller can use non-negative least squares (NNLS) to solve the matrix equation.

The at least one controller can differentiate the mono-T₂ sodium from the bi-T₂ sodium. For example, the at least one controller can differentiate the mono-T₂ sodium with short-T₂ relaxation from the bi-T₂ sodium. The at least one controller can differentiate the mono-T₂ sodium with T₂* relaxation from the bi-T₂ sodium.

The MSQ technique can, using the computer simulations, physical phantoms, and/or human subjects, separate between mono-T₂ and bi-T₂ sodium signals voxel-wise. The physics behind the technique can include the intrinsic difference in T₂ relaxation between the sodium nuclear spins: mono-exponential vs. bi-exponential decay. In the restriction of total scan time, the two-TE scheme can be better than the eight-TE scheme for smaller transfer of random noise during the separation. The measurement of T₂* spectrum from FID signal on the whole brain and the application of a global set of T₂* values (T_{2,mo}*, T_{2,bs}*, T_{2,bl}*) can be feasible for humans. In cases that are not plausible for a global set of T₂* values, multi-regional sets, or a linear (or nonlinear) combination of multi-regional sets, may be used because the separation is a voxel-wised process.

The two-component model (mono-T₂ and bi-T₂ populations) can produce a false-positive error for bi-T₂ sodium. If there are mono-T₂ and bi-T₂ sodium populations in a voxel, then they are separable. If not, such as two mono-T₂ sodium decays at different T₂ values in a voxel, they could be falsely separated into bi-T₂ sodium because they can be combined mathematically (e.g., not physically) into a bi-exponential decay mimicking a true bi-T₂ sodium decay. This kind of false positive error can stem from the fact that the separation is based on a mathematical model, instead of a physical model such as the TQF separation. Understanding these kinds of false positive errors can aid in proper interpretation of the separated bi-T₂ sodium signals.

A single mono-T₂ sodium component of short T₂* value may be separated in a voxel, such as regions in the nose and sinuses (FIGS. 8H and 9H). In this situation, the MSQ can separate it into bi-T₂ sodium of underestimated intensity. Maps of ΔB₀ and single-T₂* can help identify these mis-separated regions (FIGS. 8K-8M and 9K-9M).

The bi-T₂ sodium signal caused by the TE₁ image, as illustrated in the phantom study (FIG. 6H), may be underestimated. The separation (Eq. 2) assumes TE₁-image intensity exactly at TE₁ (e.g., requiring a very short readout time). Actual TE₁-image intensity can include an average over readout time during which short-T₂* components decay significantly if readout is relatively long, such as readout Tₛ=36.32 ms about ten times long of a short-T₂* at 3 ms in FIGS. 8A-8B and 9A-9B. Therefore, this kind of underestimation can change with readout time or pulse sequence. To mitigate the problem, two strategies may be applicable. One is to replace TE₁ value in Eq. 2 with an effective (e.g., larger) value that accounts for short-T₂* decay during the readout. The other is to shift T_{2,bs}* to a larger value. Alternatively, correction for the underestimations may be integrated into calibration of image intensity for sodium concentration during quantification process (FIG. 6I).

One challenge in sodium (²³Na) MRI can include separating signals between mono- and bi-exponential T₂ decays in the human brain, due to lack of clinically-translational solutions under the restriction of intrinsically low signal-to-noise ratio (SNR). The systems and methods of the present disclosure are directed to a technique called multi-TE single-quantum (MSQ) sodium MRI to address the challenge.

An intrinsic difference in T₂ decay between mono- and bi-exponential sodium signals can be exploited by acquiring SQ images at multiple TEs and performing voxel-based matrix inversions on these SQ images. The MSQ method can be investigated on numerical models, agar phantoms, and human brains for the feasibility on clinical scanners at 3T.

The whole brain T₂* spectrum of FID signals from the study subjects showed sparse peaks (e.g., 2-4 peaks), suggesting a global set of T₂* values (T_{2,mo}*, T_{2,bs}*, T_{2,bl}*) applicable to the separation. The simulations indicated a small impact (3.9-5.6%) of T₂* variation on accuracy of the separation, and the phantom experiments showed a high accuracy of the separation, 95.8% for mono-T₂ sodium and 72.5-80.4% for bi-T₂ sodium. The human studies demonstrated feasibility of the separation and potentials of highlighting abnormal brain regions in the bi-T₂ sodium images.

The MSQ technique has been shown, via the numerical simulations, phantom experiments, and human brain studies, to be able to separate mono- and bi-T₂ sodium signals using a two-TE sampling scheme and a global set of T₂* values.

### Definitions

No claim element herein is to be construed under the provisions of 35 U.S.C. § 112(f), unless the element is expressly recited using the phrase “means for.”

As utilized herein, the terms “approximately,” “about,” “substantially,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the disclosure as recited in the appended claims.

As utilized herein, the terms “bound” and “bi-T₂” are intended to be interchangeable when describing sodium ions in the present disclosure and to be accepted usage by those of ordinary skill in the art to which the subject matter of this disclosure pertains.

As utilized herein, the terms “free” and “mono-T₂” are intended to be interchangeable when describing sodium ions in the present disclosure and to be accepted usage by those of ordinary skill in the art to which the subject matter of this disclosure pertains.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

Any references herein to the positions of elements (e.g., “top,” “bottom,” “above,” “below”) are merely used to describe the orientation of various elements in the figures. It should be noted that the orientation of various elements may differ according to other exemplary embodiments, and that such variations are intended to be encompassed by the present disclosure.

Various embodiments are described in the general context of method steps, which may be implemented in one embodiment by a program product including computer-executable instructions, such as program code, executed by computers in networked environments. Generally, program modules include routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps.

Software and web implementations of the present invention could be accomplished with standard programming techniques with rule-based logic and other logic to accomplish the various database searching steps, correlation steps, comparison steps and decision steps. It should also be noted that the words “component” and “module,” as used herein and in the claims, are intended to encompass implementations using one or more lines of software code, and/or hardware implementations, and/or equipment for receiving manual inputs.

As used herein, the singular forms “a,” “an,” and “the” include plural referents unless the context clearly dictates otherwise. Thus, for example, the term “a member” is intended to mean a single member or a combination of members, “a material” is intended to mean one or more materials, or a combination thereof.

As used herein, the terms “about” and “approximately” generally mean plus or minus 10% of the stated value. For example, about 0.5 would include 0.45 and 0.55, about 10 would include 9 to 11, about 1000 would include 900 to 1100.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

It is important to note that the construction and arrangement of the various exemplary embodiments are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Other substitutions, modifications, changes and omissions may also be made in the design, operating conditions and arrangement of the various exemplary embodiments without departing from the scope of the present invention.

While this specification contains many specific implementation details, these should not be construed as limitations on the scope of any inventions or of what may be claimed, but rather as descriptions of features specific to particular implementations of particular inventions. Certain features described in this specification in the context of separate implementations can also be implemented in combination in a single implementation. Conversely, various features described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Although the figures and description may illustrate a specific order of method steps, the order of such steps may differ from what is depicted and described, unless specified differently above. Also, two or more steps may be performed concurrently or with partial concurrence, unless specified differently above.

It is important to note that any element disclosed in one embodiment may be incorporated or utilized with any other embodiment disclosed herein. Although only one example of an element from one embodiment that can be incorporated or utilized in another embodiment has been described above, it should be appreciated that other elements of the various embodiments may be incorporated or utilized with any of the other embodiments disclosed herein.

What is claimed is:

1. A method of quantifying sodium concentration, comprising:
extracting one or more bi-T₂ sodium signals from one or more echo time acquisitions;
separating, via a matrix equation comprising at least one of T₂ decays or T₂* decays of mono-T₂ sodium and bi-T₂ sodium, an intensity of the one or more bi-T₂ sodium signals from an intensity of one or more mono-T₂ sodium signals; and
quantifying bi-T₂ sodium concentration, mono-T₂ sodium concentration, and total sodium concentration based on the one or more echo time acquisitions;
wherein the one or more echo time acquisitions are performed with single-quantum sodium excitations.

2. The method of claim 1, further comprising acquiring one or more sodium images and a free induction decay (FID) signal.

3. The method of claim 2, further comprising acquiring the free induction decay signal from whole or part of imaging volume.

4. The method of claim 2, further comprising:
converting the free induction decay signal into T₂* spectrum; and
determining a set of T₂* values (T_{2,mo}*, T_{2,bs}*, T_{2,bl}*) for the matrix equation.

5. The method of claim 4, further comprising using a curve-fitting to the free induction decay signal to obtain the T₂* spectrum.

6. The method of claim 1, further comprising obtaining a set of T₂* values (T_{2,mo}*, T_{2,bs}*, T_{2,bl}*).

7. The method of claim 1, further comprising using a map of T₂* values (T_{2,mo}*, T_{2,bs}*, T_{2,bl}*).

8. The method of claim 1, further comprising outputting at least one of the mono-T₂ images, bi-T₂ images, and total sodium images.

9. The method of claim 1, wherein the matrix equation eliminates contamination between the one or more bi-T₂ sodium signals and the one or more mono-T₂ sodium signals.

10. The method of claim 1, further comprising eliminating contamination between the one or more mono-T₂ sodium signals and the one or more bi-T₂ sodium signals using an artificial neural network (ANN) or artificial intelligence (AI).

11. The method of claim 1, further comprising using non-negative least squares (NNLS) to solve the matrix equation.

12. The method of claim 1, further comprising differentiating the mono-T₂ sodium with short-T₂ relaxation from the bi-T₂ sodium.

13. The method of claim 1, further comprising differentiating the mono-T₂ sodium with T₂* relaxation from the bi-T₂ sodium.

14. The method of claim 1, further comprising differentiating the mono-T₂ sodium from the bi-T₂ sodium.

15. A non-transitory computer-readable medium having computer-readable instructions stored thereon that, when executed by at least one controller, cause the at least one controller to:
extract one or more bi-T₂ sodium signals from one or more echo time acquisitions;
separate, via a matrix equation comprising at least one of T₂ decays or T₂* decays of mono-T₂ sodium and bi-T₂ sodium, an intensity of the one or more bi-T₂ sodium signals from an intensity of one or more mono-T₂ sodium signals; and
quantify bi-T₂ sodium concentration, mono-T₂ sodium concentration, and total sodium concentration based on the one or more echo time acquisitions;
wherein the one or more echo time acquisitions are performed with single-quantum sodium excitations.

16. The non-transitory computer-readable medium of claim 15, wherein the at least one controller is configured to acquire one or more sodium images and a free induction decay signal.

17. The non-transitory computer-readable medium of claim 16, wherein the at least one controller is configured to acquire the free induction decay signal from whole or part of imaging volume.

18. The non-transitory computer-readable medium of claim 15, wherein the at least one controller is configured to eliminate contamination between the one or more bi-T₂ sodium signals and the one or more mono-T₂ sodium signals.

19. The non-transitory computer-readable medium of claim 15, wherein the at least one controller is configured to obtain a set of T₂* values (T_{2,mo}*, T_{2,bs}*, T_{2,bl}*).

20. The non-transitory computer-readable medium of claim 15, wherein the at least one controller is configured to output at least one of the mono-T₂ images, bi-T₂ images, and total sodium images.
